(19) United States
(12) Patent Application Publication
(10) Pub. No.: US 2025/0326628 A1
(43) Pub. Date: Oct. 23, 2025

(54) MEMBRANE CONNECTED TO PILLAR WITH SPRING CHARACTERISTICS

(71) Applicant: INVENSENSE, INC., San Jose, CA (US)

(72) Inventors: Yuki Shibano, Yamanashi (JP); Jotaro Akiyama, Yamanashi (JP); Daishi Arimatsu, Yamanashi-ken (JP); Kento Kaneko, Yamanashi-Ken (JP)

(21) Appl. No.: 19/084,436

(22) Filed: Mar. 19, 2025

Related U.S. Application Data
(60) Provisional application No. 63/637,171, filed on Apr. 22, 2024.

(51) Int. Cl. B81B 3/00; B81C 1/00

(52) U.S. Cl. CPC B81B 3/007; B81C 1/00658; B81B 2201/0257; B81B 2201/0264; B81B 2203/0127; B81B 2203/0307; B81B 2203/0315; B81B 2203/0361; B81B 2203/04; B81C 2201/0109; B81C 2201/013

(57) ABSTRACT

Microelectromechanical systems (MEMS) apparatuses and processes are described that can employ a spring pillar or flexible pillar coupled to a sensing membrane to enhance deformation of the sensing membrane while providing robust MEMS sensors or devices. Described MEMS sensors or devices can comprise an exemplary spring pillar or flexible pillar between the sensing membrane structure and the backplate structure. Exemplary spring pillar or flexible pillar can facilitate adjusting stiffness of the sensing membrane to provide MEMS sensors or devices having large sensing area and compact device size.

### CROSS-REFERENCE TO RELATED APPLICATIONS

This patent application claims priority to U.S. Provisional Patent Application No. 63/637,171, filed on Apr. 22, 2024, and entitled “MEMBRANE CONNECTED TO PILLAR WITH SPRING CHARACTERISTICS.” In addition, this application is related to U.S. Non-Provisional patent application Ser. No. 18/953,016, filed on Nov. 19, 2024, and entitled “SEALED CAVITY FOR A CAPACITIVE SENSING DEVICE.” The entirety of these applications are hereby incorporated by reference herein.

### TECHNICAL FIELD

This disclosure generally relates to Microelectromechanical systems (MEMS) devices and more particularly relates to MEMS devices comprising a flexible or spring pillar.

### BACKGROUND

Microelectromechanical systems (MEMS) is a class of structures and/or devices that are fabricated using semiconductor-like processes. MEMS structures and/or devices exhibit mechanical characteristics that include the ability to move or to deform. Examples of MEMS devices include, but are not limited to, gyroscopes, accelerometers, magnetometers, pressure sensors, radio-frequency components, and so on. Silicon wafers that include MEMS structures are referred to as MEMS wafers. Unique challenges exist to provide MEMS devices and/or structures with improved performance and reliability.

For example, MEMS membrane structures are often used as moving members in MEMS devices or sensors to respond to an external input or to create output, where the MEMS membrane structures are anchored at the periphery and free to deflect in response to the input away from anchor, near the center. Deformation of the anchored MEMS membrane structure is limited at the anchor, and maximum displacement occur at the MEMS membrane structure center, becoming less toward the anchored areas. Thus, MEMS membrane structure areas close to the anchors do not contribute to MEMS device transducer performance, thereby limiting MEMS device performance for a given MEMS die area.

For instance, MEMS structures and/or devices such as acoustic sensors, ultrasonic sensors, pressure sensors, sense changes in air pressure either by sensing pressure waves or other pressure changes by vibration or deflection of the MEMS membrane structures. Accordingly, MEMS membrane structures are required to rapidly respond to small changes in pressure, such as in a pressure wave, and they are required to be able to withstand larger external loads, e.g., pressure changes caused by impacting air, atmospheric pressure changes, and/or external mechanical shocks. As a result, stiffness control of MEMS membrane structures is an ongoing engineering challenge subject to design tradeoffs, including but not limited to device package size, sensitivity, noise performance, and robustness. As a non-limiting example, while smaller MEMS membrane structures can be expected to be more robust in the presence of large external loads and have a reduced package size, MEMS membrane structure sensing area is reduced. Furthermore, other conventional techniques to increase MEMS membrane structure stiffness while preserving sensing area have other drawbacks as further described herein.

It is thus desired to provide improved MEMS devices, designs, and processes that address these and other deficiencies. The above-described deficiencies are merely intended to provide an overview of some of the problems of conventional implementations, and are not intended to be exhaustive. Other problems with conventional implementations and techniques and corresponding benefits of the various aspects described herein may become further apparent upon review of the following description.

### SUMMARY

The following presents a simplified summary of the specification to provide a basic understanding of some aspects of the specification. This summary is not an extensive overview of the specification. It is intended to neither identify key or critical elements of the specification nor delineate any scope particular to any embodiments of the specification, or any scope of the claims. Its sole purpose is to present some concepts of the specification in a simplified form as a prelude to the more detailed description that is presented later.

Accordingly, various non-limiting embodiments of MEMS devices or sensors are provided that can employ MEMS membrane structures, such as a MEMS sensing membrane structure, that can comprise or be associated with a pillar structure that supports the MEMS sensing membrane structure, and which pillar structure can act in concert with a spring structure, such as a spring membrane structure comprising a spring membrane, that acts in effect as a spring, and which spring membrane structure and pillar structure (i.e., collectively referred to herein as a spring pillar or a flexible pillar) can facilitate providing a predetermined level of stiffness of the MEMS sensing membrane structure in response to and external input, as described herein. As a non-limiting example, exemplary spring membrane structure and pillar structure can facilitate providing a predetermined level of stiffness of the MEMS sensing membrane structure, based on lateral thickness of the pillar structure, based on an area of the spring membrane, based on a thickness of the spring membrane, and so on, as further described herein.

MEMS apparatuses and processes are described that can employ a spring pillar or flexible pillar coupled to a sensing membrane to enhance deformation of the sensing membrane while providing robust MEMS sensors or devices. Described MEMS sensors or devices can comprise an exemplary spring pillar or flexible pillar between the sensing membrane structure and the backplate structure. Exemplary spring pillar or flexible pillar can facilitate adjusting stiffness of the sensing membrane to provide MEMS sensors or devices having large sensing area and compact device size.

These and other embodiments are described in more detail below.

### BRIEF DESCRIPTION OF THE DRAWINGS

Various non-limiting embodiments are further described with reference to the accompanying drawings in which:

FIG. 1 provides a cross-section of exemplary MEMS devices or sensors comprising an exemplary pillar structure and an exemplary spring membrane structure that depicts various non-limiting aspects described herein;

FIG. 2 provides an expanded cross-section of exemplary MEMS devices or sensors 100 comprising an exemplary pillar structure and an exemplary spring membrane structure that depicts various non-limiting aspects described herein;

FIG. 3 depicts a functional block diagram that illustrates non-limiting aspects applicable to exemplary MEMS devices or sensors comprising an exemplary pillar structure and an exemplary spring membrane structure described herein;

FIG. 4 depicts further non-limiting aspects applicable to exemplary MEMS devices or sensors described herein;

FIG. 5 illustrates particular aspects of non-limiting embodiments comprising an exemplary pillar structure and an exemplary spring membrane structure suitable for use in exemplary MEMS devices or sensors described herein;

FIGS. 6-23 illustrate example, non-limiting, cross-sectional views of exemplary MEMS devices or sensors comprising an exemplary pillar structure and an exemplary spring membrane structure undergoing fabrication processes in accordance with one or more embodiments described herein;

FIG. 24 provides a cross-section of other exemplary MEMS devices or sensors comprising an exemplary pillar structure and an exemplary spring membrane structure that depicts various non-limiting aspects described herein;

FIGS. 25-43 illustrate example, non-limiting, cross-sectional views of further exemplary MEMS devices or sensors comprising an exemplary pillar structure and an exemplary spring membrane structure undergoing fabrication processes in accordance with one or more embodiments described herein;

FIG. 44 illustrates particular aspects of non-limiting embodiments comprising an exemplary pillar structure and an exemplary spring membrane structure suitable for use in exemplary MEMS devices or sensors described herein;

FIG. 45 provides a non-limiting flow diagram of exemplary methods according to various non-limiting aspects as described herein; and

FIG. 46 provides a non-limiting flow diagram of exemplary methods according to various non-limiting aspects as described herein.

### DETAILED DESCRIPTION

### Overview

While a brief overview is provided, certain aspects of the subject disclosure are described or depicted herein for the purposes of illustration and not limitation. Thus, variations of the disclosed embodiments as suggested by the disclosed apparatuses, systems, and methodologies are intended to be encompassed within the scope of the subject matter disclosed herein.

As described above, MEMS membrane structures are required to rapidly respond to small changes in pressure, such as in a pressure wave, and they are required to be able to withstand larger external loads, e.g., pressure changes caused by impacting air, atmospheric pressure changes, and/or external mechanical shocks. As a result, stiffness control of MEMS membrane structures is an ongoing engineering challenge subject to design tradeoffs, including but not limited to device package size, sensitivity, noise performance, and robustness. As a non-limiting example, while smaller MEMS membrane structures can be expected to be more robust in the presence of large external loads and have a reduced package size, MEMS membrane structure sensing area is reduced.

Furthermore, other conventional techniques to increase MEMS membrane structure stiffness while preserving sensing area have other drawbacks. For instance, for a given sensing area, a fixed pillar under the MEMS membrane structure can increase stiffness of the MEMS membrane structure. However, deformation of the MEMS membrane structure is not flat, because there is no deformation of the MEMS membrane structure near the area of the pillar, as further described herein. In addition, it is difficult to control the stiffness of the MEMS membrane structure by the pillar itself, and as a result, stiffness of the MEMS membrane structure can easily become too large for a desired application.

To these and/or related ends, various aspects of MEMS sensors, devices, systems, and methods therefor are described. Various embodiments of the subject disclosure are described herein for purposes of illustration, and not limitation. For example, embodiments of the subject disclosure are described herein in the context of a MEMS sensor, such as a MEMS pressure sensor. However, it can be appreciated that various aspects of the subject disclosure is not so limited. As further detailed below, various exemplary implementations may find application in other areas of MEMS sensor design and/or packaging, without departing from the subject matter described herein.

### EXEMPLARY EMBODIMENTS

One or more embodiments are now described more fully hereinafter with reference to the accompanying drawings in which example embodiments are shown. In the following description, for purposes of explanation, numerous specific details are set forth in order to provide a thorough understanding of the various embodiments.

Various references are made herein to compositional features of the disclosed MEMS devices or sensors, resulting from various semiconductor-like processes and materials used in exemplary MEMS fabrication processes. It can be understood that there may be suitable substitutions or alternative materials and/or processes to accomplish the described techniques, devices, processes, and so on. As such, descriptions herein of the various semiconductor-like processes and materials used in exemplary MEMS fabrication processes is intended to provide understanding of the appended claims without limitation.

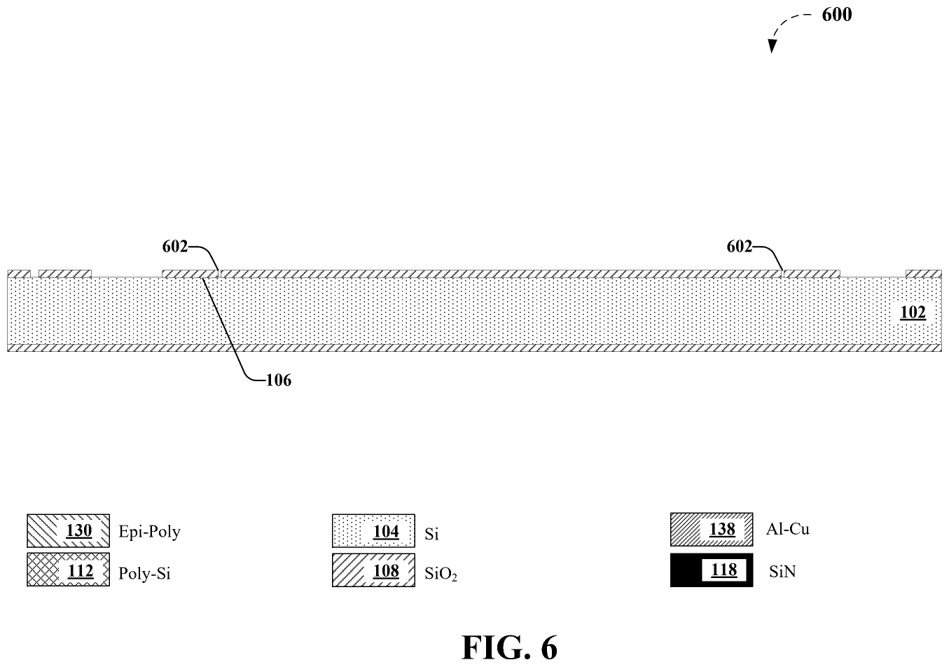

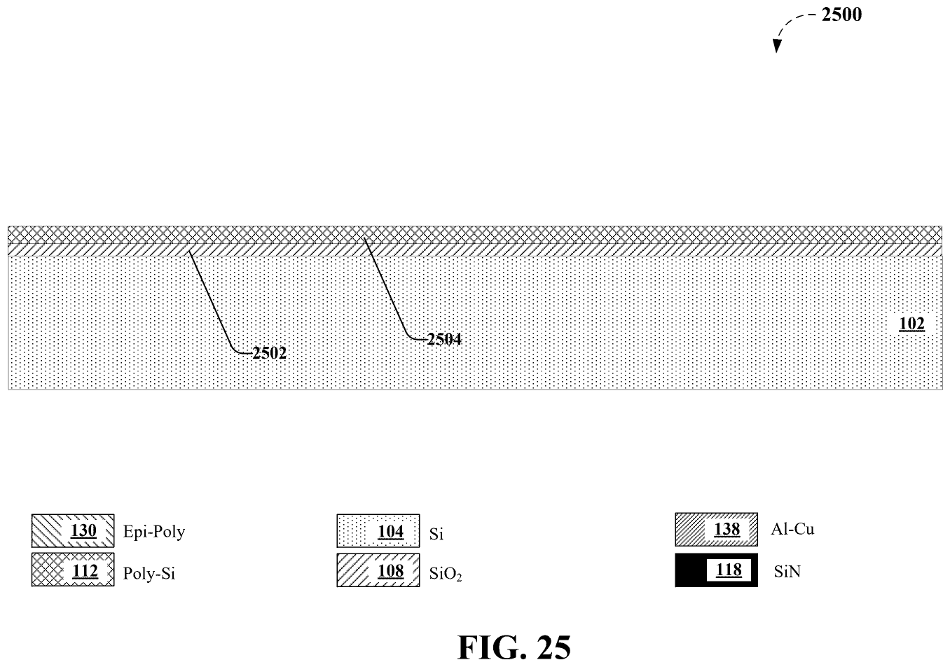

For example, silicon dioxide (SiO₂) can be deposited via an exemplary MEMS fabrication process comprising one or more plasma-enhanced chemical vapor deposition processes (PECVD) employing tetraethylorthosilicate (TEOS) resulting in layers/structures that are derived from such processes including any lithographic patterning and/or etch processes, as further described herein regarding FIGS. 6-23 and/or FIGS. 25-43. In another non-limiting example, SiO₂ can be deposited via an exemplary MEMS fabrication process comprising one or more low pressure chemical vapor deposition processes (LPCVD) TEOS processes (LPCVD) resulting in layers/structures that are derived from such processes including any lithographic patterning and/or etch processes.

In addition, silicon nitride (SiN) can be deposited via an exemplary MEMS fabrication process comprising one or more LPCVD Low Stress Silicon Nitride (LSN) deposition processes resulting in layers/structures that are derived from such processes including any lithographic patterning and/or etch processes, as further described herein regarding FIGS. 6-23 and/or FIGS. 25-43. In another non-limiting example, SiN can be deposited via an exemplary MEMS fabrication process comprising one or more PECVD LSN deposition processes resulting in layers/structures that are derived from such processes including any lithographic patterning and/or etch processes.

As another example, polycrystalline silicon (poly-Si) can be deposited via an exemplary MEMS fabrication process comprising one or more in-situ phosphorous doped polycrystalline silicon deposition processes resulting in layers/structures that are derived from such processes including any lithographic patterning and/or etch processes, as further described herein regarding FIGS. 6-23 and/or FIGS. 25-43.

Furthermore, metal alloy such as aluminum-copper (AlCu), chromium-gold (CrAu) can be deposited via an exemplary MEMS fabrication process comprising one or more metal deposition processes resulting in layers/structures that are derived from such processes including any lithographic patterning and/or etch processes. In still another non-limiting example, where processes are described as employing a deposition of SiN, for instance, to seal a chamber in exemplary MEMS devices that is exposed via release etching, it can be understood that other suitable materials such as SiO₂, metal, or another suitable material (e.g., epitaxial deposition of polysilicon (epi-poly-Si)) can be employed to facilitate sealing of such a chamber at a predetermined chamber pressure.

Accordingly, various non-limiting embodiments of MEMS devices or sensors are provided that can employ MEMS membrane structures, such as a MEMS sensing membrane structure, that can comprise or be associated with a pillar structure that supports the MEMS sensing membrane structure, and which pillar structure can act in concert with a spring structure, such as a spring membrane structure comprising a spring membrane, that acts in effect as a spring, and which spring membrane structure and pillar structure (i.e., collectively referred to herein as a spring pillar or a flexible pillar) can facilitate providing a predetermined level of stiffness of the MEMS sensing membrane structure in response to and external input, as described herein. As a non-limiting example, exemplary spring membrane structure and pillar structure can facilitate providing a predetermined level of stiffness of the MEMS sensing membrane structure, based on lateral thickness of the pillar structure, based on an area of the spring membrane, based on a thickness of the spring membrane, and so on, as further described herein.

For example, as further described herein, exemplary embodiments of a spring pillar can facilitate achieving gradual deformation of an associated MEMS sensing membrane structure, because the associated MEMS sensing membrane structure associated with the spring pillar has room to deform as a result of the spring characteristics provided by the spring membrane structure and pillar structure. In a further non-limiting aspect, various embodiments provide MEMS sensing membrane structure with varying stiffness according to design requirements as a result of the ability to modulate the spring constant of the spring pillar, which can address drawbacks of conventional fixed pillar solutions.

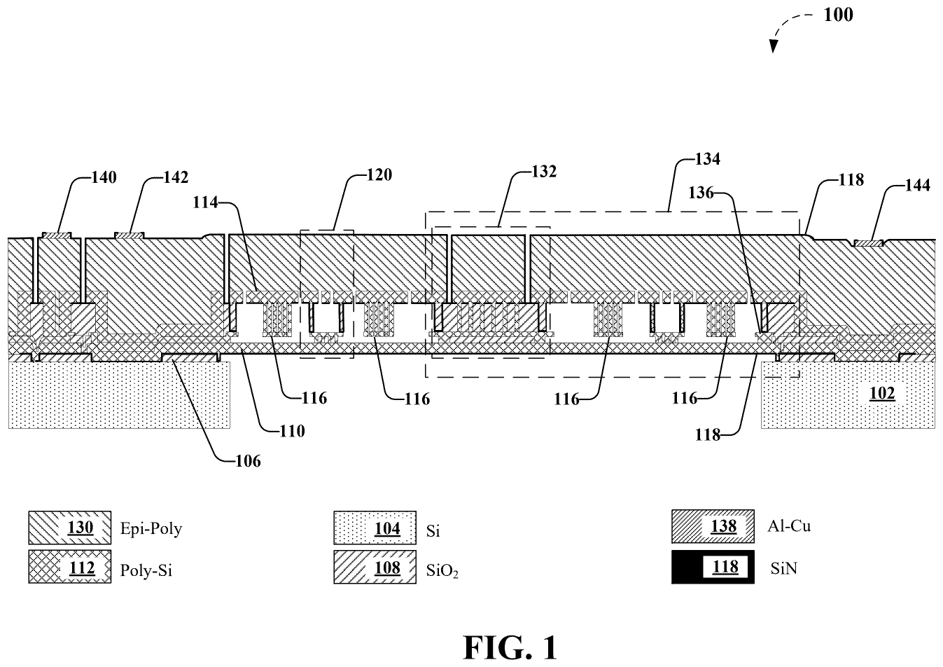

Accordingly, FIG. 1 provides a cross-section of exemplary MEMS devices or sensors 100 comprising an exemplary pillar structure and an exemplary spring membrane structure that depicts various non-limiting aspects described herein. For instance, exemplary MEMS devices or sensors 100 can comprise a device substrate 102 (e.g., a wafer substrate). In a non-limiting aspect, the device substrate 102 can comprise a silicon (Si) 104 wafer, for example. In addition, exemplary MEMS devices or sensors 100 can comprise a device insulating layer 106. For instance, exemplary MEMS devices or sensors 100 can comprise a device insulating layer 104 that can comprise a layer of deposited and/or patterned SiO₂ 108, as further described herein.

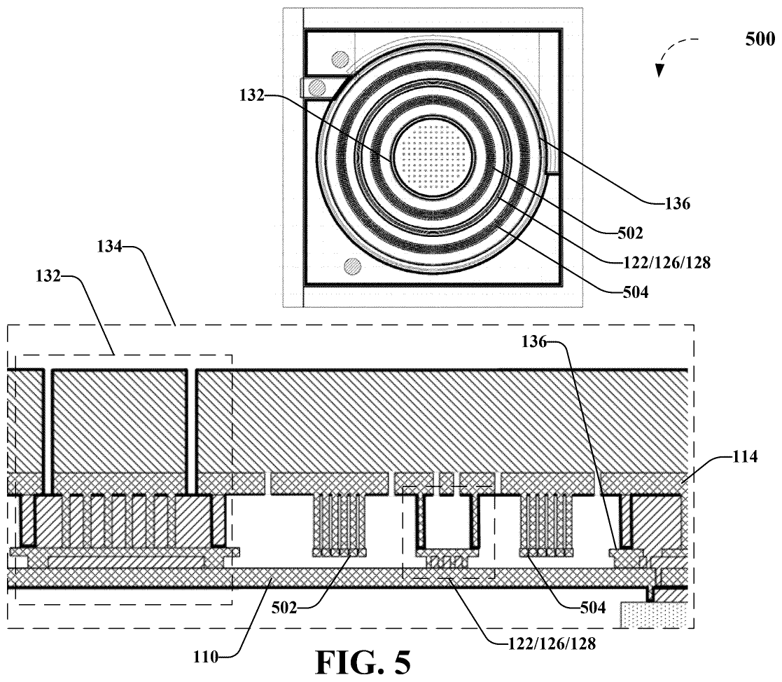

In yet other non-limiting embodiments, exemplary MEMS devices or sensors 100 can further comprise a sensing membrane structure 110, which can be configured to deform when exposed to an external input. In a non-limiting aspect, exemplary sensing membrane structure 110 can comprise one or more depositions of poly-Si 112, for example, as further described herein. In further non-limiting embodiments, exemplary MEMS devices or sensors 100 can further comprise backplate structure 114 which can comprise or be associated with one or more electrodes 116 associated with a backplate structure 114 and configured to sense deformation of the sensing membrane structure 110. In non-limiting aspects, exemplary one or more electrodes 116 and the backplate structure 114 can comprise a layer of deposited and/or patterned poly-Si 112, for example, as further described herein. As further described herein, regarding FIG. 5, one or more electrodes 116 of exemplary MEMS devices or sensors 100 can comprise one or more of an inner bottom electrode and an outer bottom electrode coupled to backplate structure 114.

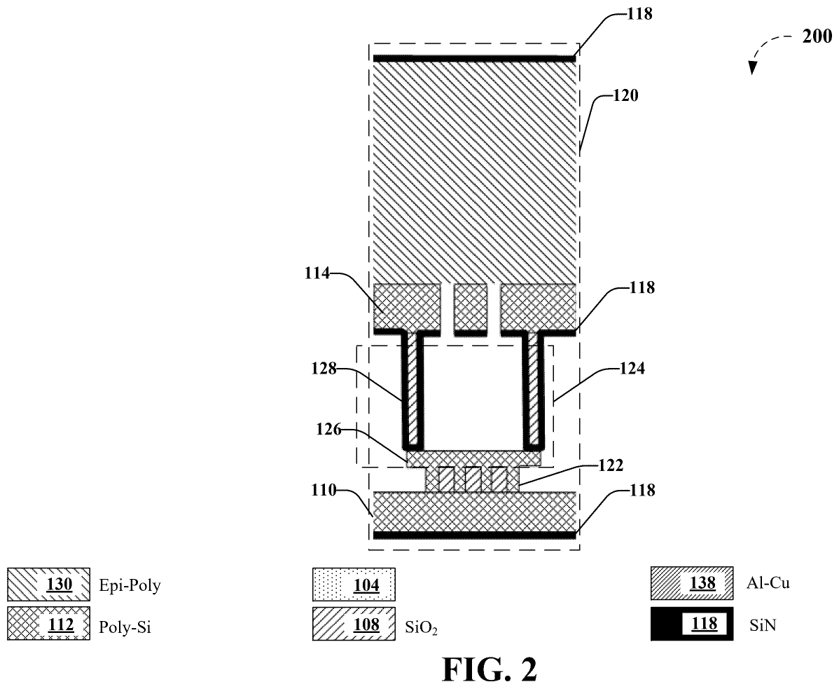

FIG. 2 provides an expanded cross-section 200 of exemplary MEMS devices or sensors 100 comprising an exemplary pillar structure and an exemplary spring membrane structure that depicts various non-limiting aspects described herein. In further non-limiting embodiments, exemplary MEMS devices or sensors 100 can further comprise one or more spring pillar or flexible pillar shown in inset 120 of the exemplary MEMS device or sensor 100, which can comprise a pillar structure 122 coupled to one of the sensing membrane structure 110 or the backplate structure 114 and a spring membrane structure 124 comprising a spring membrane 126 and an anchor structure 128, for example, as further depicted herein in FIG. 2. In a non-limiting aspect, for an exemplary spring membrane structure 124 comprising a spring membrane 126 and an anchor structure 128, the exemplary pillar structure 122 can be coupled between one of the sensing membrane structure 110 or the backplate structure 114 and the spring membrane 126, and the anchor structure 128 can be coupled between the spring membrane 126 and the other of the sensing membrane structure 124 or the backplate structure 114. In a non-limiting aspect, as shown for one or more spring pillar or flexible pillar shown in inset 120, an exemplary spring pillar or flexible pillar shown can comprise various layers of deposited and/or patterned SiO₂ 108, poly-Si 112, and/or SiN 118, and for example, as further described herein regarding FIGS. 6-23. In still further non-limiting embodiments, exemplary MEMS devices or sensors 100 can further comprise one or more layers of deposited and/or patterned SiN 118 (e.g., for passivation, isolation, etch stop) for example, as further described herein.

In yet other non-limiting embodiments, exemplary MEMS devices or sensors 100 can further comprise can comprise one or more depositions of epi-poly-Si 130, for example, as further described herein, for example, to further define or provide structure to exemplary MEMS devices or sensors 100. In addition, exemplary MEMS devices or sensors 100 are depicted configured with a donut-shaped sensing membrane structure 110 and backplate structure 114 with a center fixed column structure 132, for example, as described in U.S. Non-Provisional patent application Ser. No. 18/953,016, filed on Nov. 19, 2024, and entitled “SEALED CAVITY FOR A CAPACITIVE SENSING DEVICE, which application is incorporated by reference herein. Inset 134 provides further detail regarding the one or more electrodes 116 of exemplary MEMS devices or sensors 100, comprising one or more of an inner bottom electrode and an outer bottom electrode coupled to backplate structure 114 as well as exemplary one or more spring pillar, which is configured between center column structure 132 and the sensing membrane structure 110 external anchor 136 located at the lateral etch stop, as further described herein, regarding FIG. 5 and FIGS. 6-23.

In yet other non-limiting embodiments, exemplary MEMS devices or sensors 100 can further comprise one or more depositions of metal 138 (e.g., Al—Cu 138), for example, as further described herein, for example, to one or more of substrate contact pad 140, sensing membrane structure 110 contact pad 142, and/or backplate structure 114 contact pad 144, for example, as further described herein regarding FIGS. 6-23. Accordingly, various embodiments described herein can employ a pillar structure 122 coupled to one of the sensing membrane structure 110 or the backplate structure 114 and a spring membrane structure 124 comprising a spring membrane 126 and an anchor structure 128, which pillar structure 122 and spring membrane structure 124 can act as a spring coupled to the sensing membrane structure 110, which can facilitate adjusting the stiffness of the sensing membrane structure 110.

It can be understood that the sensing membrane structure 110, the pillar structure 122 coupled to one of the sensing membrane structure 110 or the backplate structure 114, the spring membrane structure 124 comprising a spring membrane 126 and an anchor structure 128 are shown in a cross-section, which limits the depiction of the characteristics of their respective configurations. As further described herein, the number, positioning, configuration (shape and/or construction), and arrangement (relative to other components) of the exemplary sensing membrane structure 110 array can vary, without limitation, for example, as further described herein regarding FIGS. 5-43.

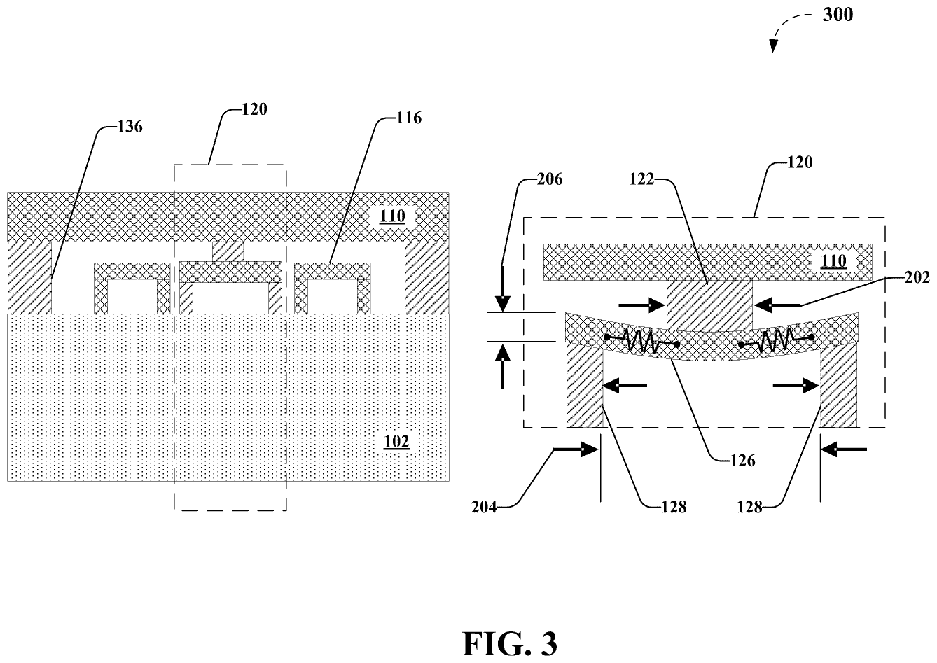

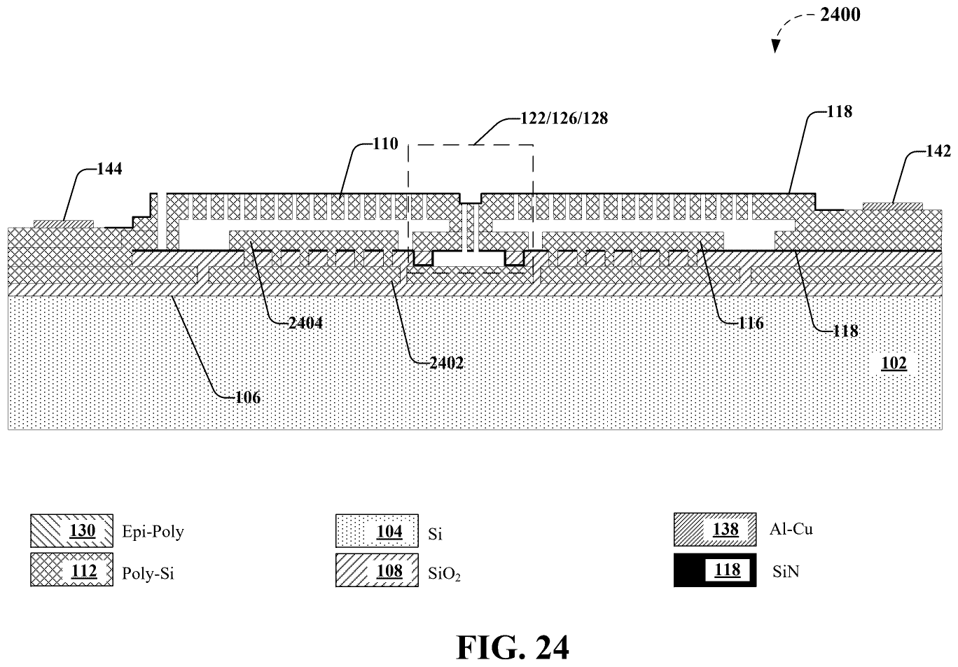

FIG. 3 depicts a functional block diagram 300 that illustrates non-limiting aspects applicable to exemplary MEMS devices or sensors 100 comprising an exemplary pillar structure 122 and an exemplary spring membrane 126 structure described herein. As described above, various embodiments described herein can employ a pillar structure 122 coupled to one of the sensing membrane structure 110 or the backplate structure 114 (shown in FIG. 3 as coupled to the substrate comprising a Si 102 wafer, which substrate supports the one or more electrodes 116 associated with the backplate structure 114, for example, as described regarding FIGS. 24-43) and a spring membrane structure 124 comprising a spring membrane 126 and an anchor structure 128, which pillar structure 122 and spring membrane structure 124 can act as a spring coupled to the sensing membrane structure 110, which can facilitate adjusting the stiffness of the sensing membrane structure 110. In non-limiting aspects, the exemplary spring membrane structure 124 and/or the exemplary pillar structure 122 can be configured such that one or more can provide a predetermined level of stiffness of the sensing membrane structure in response to an external input on the sensing membrane structure 110 based on a lateral thickness 202 of the pillar structure 122, an area of the spring membrane 126 (e.g., as indicated by dimension 204 of spring membrane 126), or a thickness 206 of the spring membrane 126, which can facilitate adjusting the design compliance of sensing membrane structure 110 can be adjusted without changing the size of the sensing membrane structure 110. As a non-limiting example, by changing lateral thickness 202 of the pillar structure 122, such as by trim etching (e.g., via very high frequency (VHF) isotropic etching), exemplary spring pillar or flexible pillar structure as described herein can provide the ability to adjust compliance of the sensing membrane structure 110 of exemplary MEMS devices or sensors 100, which compliance can be tested/verified at electrical test (e.g., via resonance frequency testing).

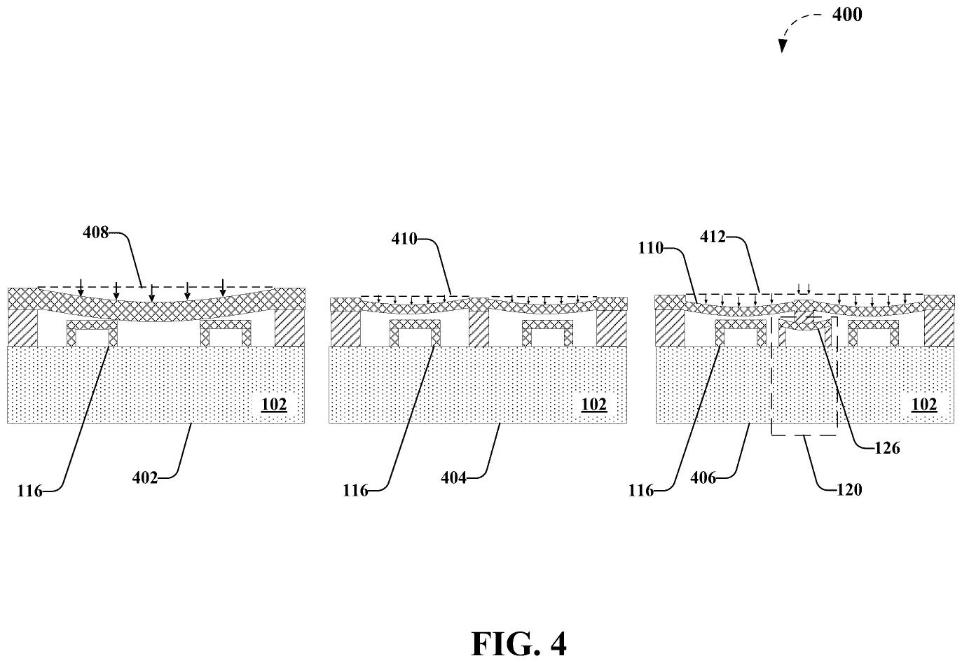

FIG. 4 depicts further non-limiting aspects applicable to exemplary MEMS devices or sensors 100 described herein. For instance, FIG. 4 provides a side-by-side comparison 400 of block diagrams of a MEMS device 402 without any pillar, a MEMS device 404 with a fixed pillar, and a MEMS device 406 with a spring pillar, to illustrate several aspects of various embodiments as further described herein. It is illustrated in FIG. 4 that for the MEMS device 402 without any pillar, deflection volume 408 by a given pressure can be expected to be large, sacrificing robustness for large loads, which can be mitigated by employing smaller MEMS sensing membrane size and smaller sensing area. For the MEMS device 404 with a fixed pillar, robustness for large loads can be improved over the MEMS device 402 without any pillar, with deflection volume 410 by a given pressure expected to be small, trading robustness for large loads. This can be mitigated by employing larger MEMS sensing membrane size, but such would result in larger MEMS sensing membrane size, leading to larger MEMS device chip and package sizes. However, it can also be shown that, compared to a small sensing membrane (e.g., for robustness) MEMS device 402 without any pillar with a larger membrane size in the MEMS device 404 with a fixed pillar, smaller deformations 410 (e.g., via smaller external input variations) can result, making it difficult to accommodate such small deformations 410 while attempting to achieve MEMS devices 404 with a fixed pillar and roughly the same membrane size as for the small membrane (e.g., for robustness) MEMS device 402 without any pillar.

For the MEMS device 406 with an exemplary spring pillar, according to non-limiting aspects described herein, robustness for large loads can be improved over the MEMS device 402 without any pillar, with deflection volume 412 by a given pressure expected to be larger than deflection volume 410 for MEMS device 404 with a fixed pillar, without trading robustness for large loads, and while allowing for smaller MEMS device and package sizes compared to MEMS device 404 with a fixed pillar. For instance, it can also be seen that, compared to equivalent sensing membrane size MEMS device 404 with a fixed pillar, larger deformations 412 (e.g., via same external input variations) can result, because the spring membrane structure 124 comprising a spring membrane 126 and an anchor structure 128 can deflect, allowing for more deflection 412 of sensing membrane structure 110. In addition, as described above regarding FIG. 3, compliance of sensing membrane structure 110 (e.g., for a given external input) can be adjusted by varying a lateral thickness 202 of the pillar structure 122, an area of the spring membrane 126 (e.g., as indicated by dimension 204 of spring membrane 126), or a thickness 206 of the spring membrane 126, while keeping the same sensing membrane structure 110 membrane size.

It can also be shown that, compared to equivalent sensing membrane size MEMS device 404 with a fixed pillar, to maintain deformation 410 (e.g., via same external input variations) as deformation 412 for MEMS device 406 with an exemplary spring pillar, membrane thickness for the MEMS device 404 with a fixed pillar would have to increase roughly by a factor of two for a particular device configuration, which would result in increased material deposition costs and process times. Moreover, as further described herein, deflection 412 volume for MEMS device 406 with an exemplary spring pillar can be improved/optimized by the design and/or location of exemplary spring pillar or flexible pillar. In another non-limiting aspect, compared to equivalent sensing membrane thickness and size MEMS device 404 with a fixed pillar, to maintain deformation 410 (e.g., via same external input variations) as deformation 412 for MEMS device 406 with an exemplary spring pillar, sensing membrane for the MEMS device 404 with a fixed pillar can be pre-stressed, increasing the sensing membrane tension. However, control of such sensing membrane tension can be difficult and presents the risk of reducing the margin to or exceeding fracture strength of the sensing membrane.

FIG. 5 illustrates particular aspects 500 of non-limiting embodiments comprising an exemplary pillar structure 122 and an exemplary spring membrane structure 126 suitable for use in exemplary MEMS devices or sensors 100 described herein. Inset 134 of FIG. 1, as expanded in FIG. 5, provides further detail regarding the one or more electrodes 116 of exemplary MEMS devices or sensors 100, comprising one or more of an inner bottom electrode 502 and an outer bottom electrode 504 coupled to backplate structure 114 as well as exemplary one or more spring pillar, e.g., exemplary pillar structure 122, exemplary spring membrane structure 126, anchor structure 128, which is configured between center column structure 132 and the sensing membrane structure 110 external anchor 136 located at the lateral etch stop for donut-shaped sensing membrane structure 110 of a sealed-cavity, capacitive sensing device, such as MEMS devices or sensors 100 (e.g., comprising a pressure sensor, an acoustic sensor, an ultrasonic sensor), as further described herein, regarding FIGS. 6-23. In a non-limiting embodiment, MEMS devices or sensors 100 (e.g., comprising a pressure sensor, an acoustic sensor, an ultrasonic sensor) can comprise a donut-shaped sensing membrane structure 110 of a sealed-cavity, vacuum chamber, capacitive sensing device, that can provide large sensing area, robustness to large external loads, and sensitivity to small pressure level variations, and adjustable compliance of sensing membrane structure 110 (e.g., for a given external input), by incorporating various aspects described herein.

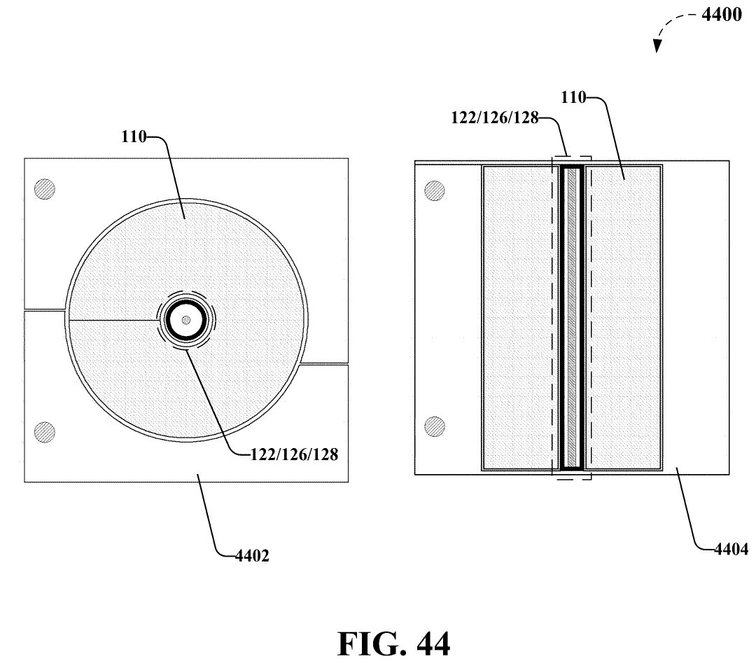

It can be understood that while the various embodiments disclosed in FIGS. 1-5 are directed a donut-shaped sensing membrane structure 110, the descriptions herein of the various devices is intended to provide understanding of the appended claims without limitation. As such, it can be further understood that there may be suitable substitutions or alternative materials, structures, configurations, and/or processes to accomplish the described techniques, devices, structures, processes, and so on. As non-limiting examples, sensing membrane structure 110 configuration, numbers, shapes, or arrangements of spring pillar or flexible pillar elements, number of etch release structures, and so on can vary, without limitation. As non-limiting examples, FIGS. 5 and 44 provide variations directed to sensing membrane structure 110 and/or backplate structure 114 variations. As a further non-limiting example, FIGS. 1, 5-23, and 24-44 provide various process and/or configuration variations, which are intended to be included in the recited claims.

FIGS. 6-23 illustrate example, non-limiting, cross-sectional views of exemplary MEMS devices or sensors comprising an exemplary pillar structure and an exemplary spring membrane structure undergoing fabrication processes in accordance with one or more embodiments described herein.

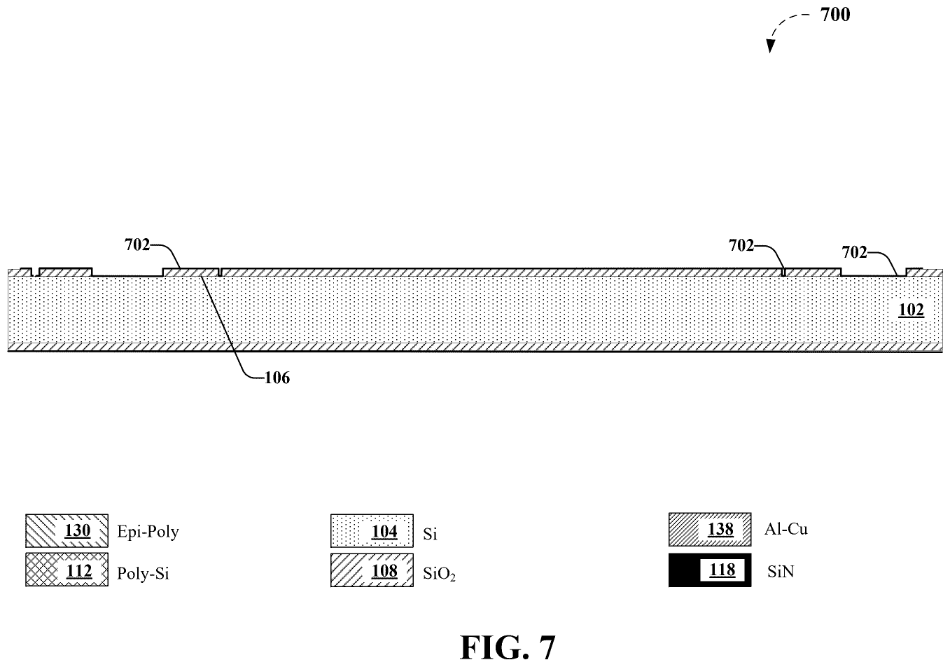

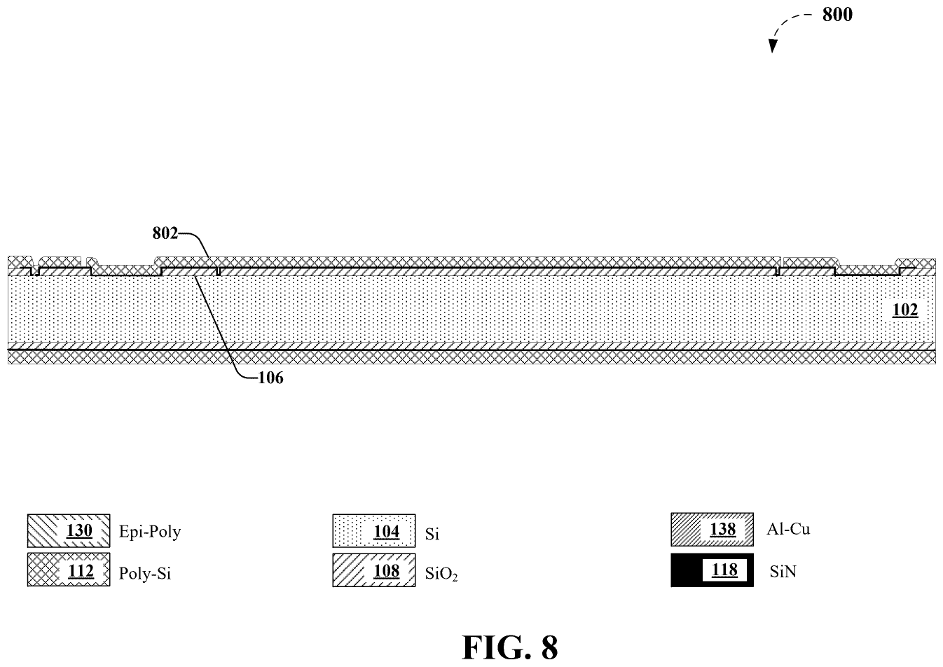

For instance, FIG. 6 depicts 600 exemplary MEMS device or sensor 100 undergoing fabrication processes in which an exemplary device substrate 102 (e.g., a wafer substrate, a silicon 104 wafer) receives a device insulating layer 106 comprising a layer of deposited and/or patterned SiO₂ 108, as further described herein, regarding FIG. 1, for example, which can define sensing membrane structure 110 lateral etch stop 602. In another non-limiting example, FIG. 7 depicts 700 exemplary MEMS device or sensor 100 undergoing fabrication processes in which a layer 702 comprising a layer of deposited and/or patterned SiN 118 can be deposited on top of the fixed electrode structure 108, as further described herein, regarding FIG. 1, for example. In a further non-limiting example, FIG. 8 depicts 800 exemplary MEMS device or sensor 100 undergoing fabrication processes in which a sensing membrane structure 110 comprising a layer 802 of deposited and/or patterned poly-Si 112 can be deposited/patterned over layer 702 of SiN 118, as further described herein, regarding FIG. 1.

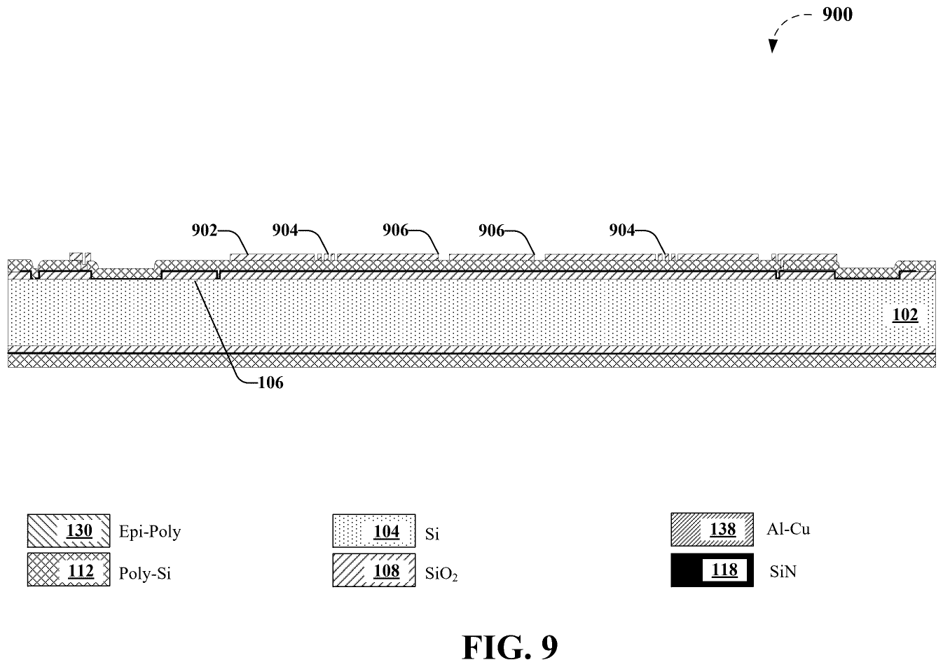

In another non-limiting example, FIG. 9 depicts 900 exemplary MEMS devices or sensors 100 undergoing fabrication processes in which a layer of deposited and/or patterned SiO₂ 108, can be developed as a sacrificial layer 902 over the sensing membrane structure 110 and under the backplate structure 114, electrodes 116, and spring membrane 126, thereby defining the gap between such structures, and portions of which layer 902 can be release etched as further described herein to define, in part, the cavity, chamber, or gap therebetween. In addition, FIG. 9 depicts 900 exemplary MEMS devices or sensors 100 undergoing fabrication processes in which a layer 902 of deposited and/or patterned SiO₂ 108 can be patterned (e.g., via lithography, etch) to define portions 904 of pillar structure 122 associated with exemplary spring pillar and portions 906 of center fixed column structure 132.

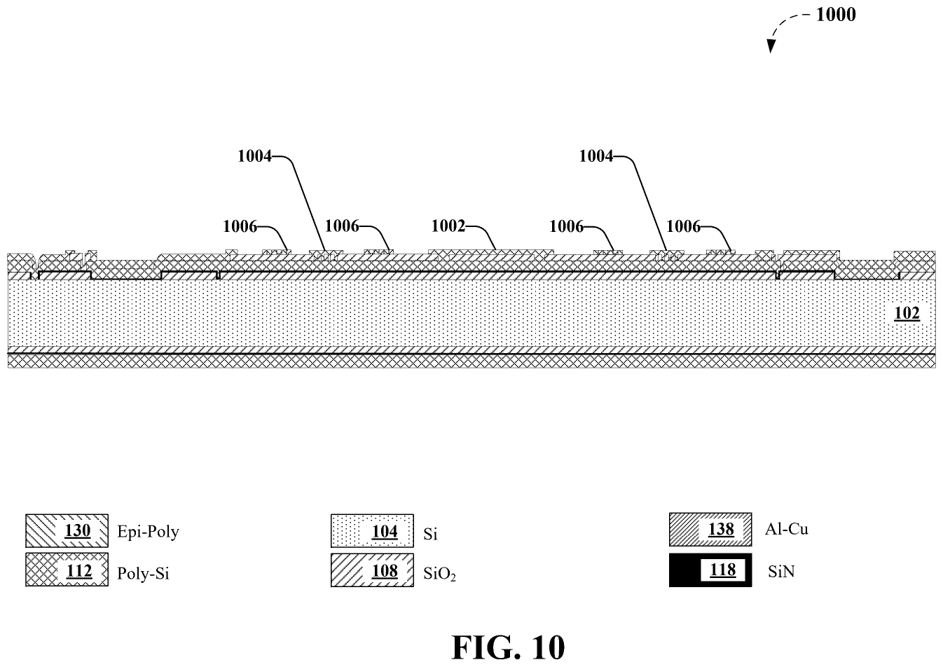

In addition, FIG. 10 depicts 1000 exemplary MEMS device or sensor 100 undergoing fabrication processes in which electrodes 116 and spring membrane 126 comprising a layer 1002 of deposited and/or patterned poly-Si 112 can be deposited/patterned over sacrificial layer 902 of SiO₂ 108, as further described herein, regarding FIG. 1, for example. In addition, FIG. 10 depicts 1000 exemplary MEMS devices or sensors 100 undergoing fabrication processes in which a layer 1002 of deposited and/or patterned poly-Si 112 can be patterned (e.g., via lithography, etch) to define portions 1004 of spring membrane 126 associated with exemplary spring pillar and portions 1006 of electrodes 116.

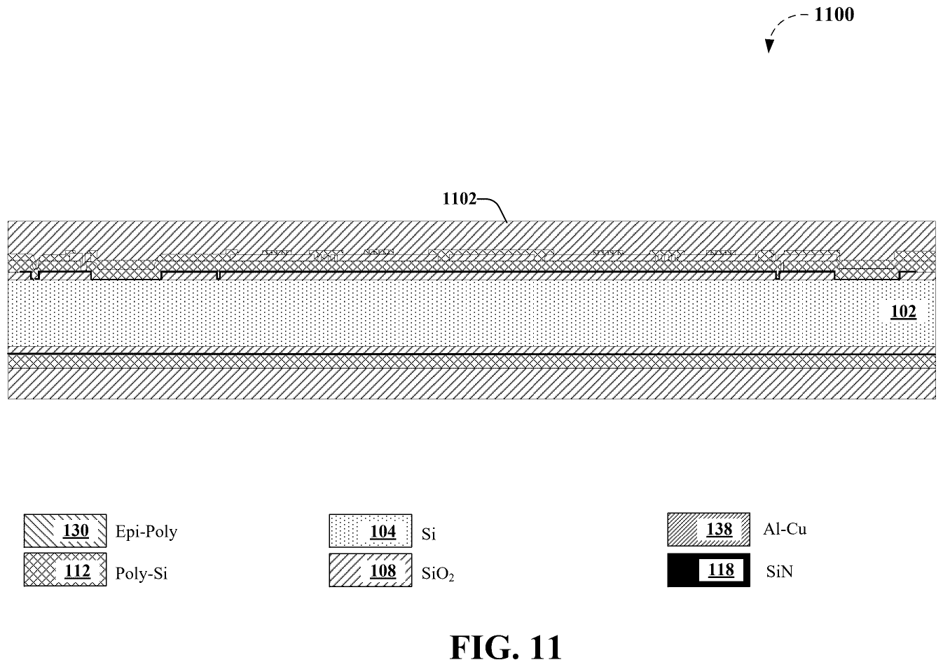

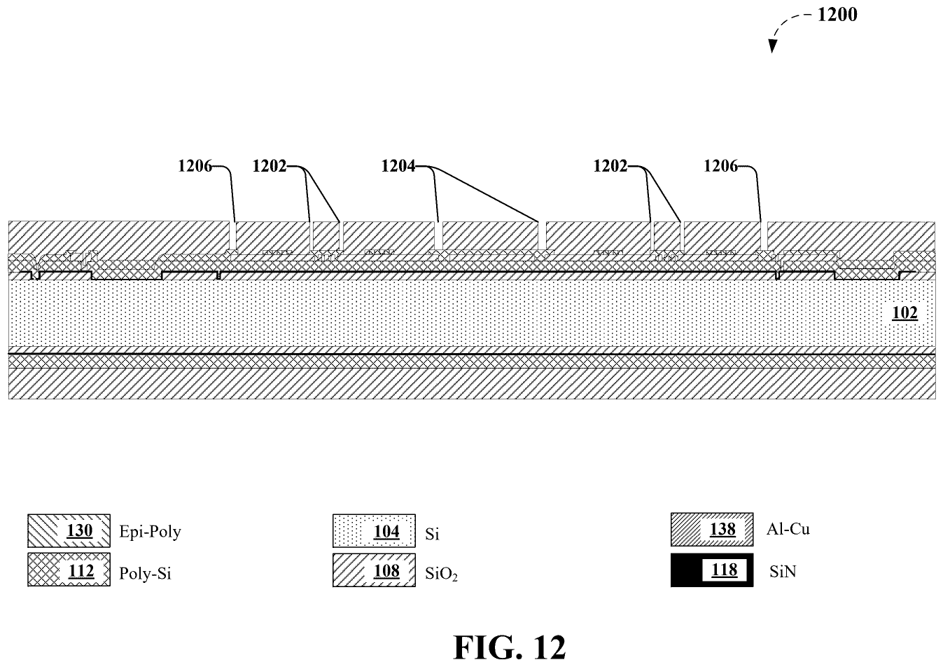

In another non-limiting example, FIG. 11 depicts 1100 exemplary MEMS devices or sensors 100 undergoing fabrication processes in which a layer of deposited and/or patterned SiO₂ 108, can be developed as a sacrificial layer 1102 over layer 1002 of deposited and/or patterned poly-Si 112. Exemplary MEMS devices or sensors 100 can then undergo a chemical-mechanical polishing (CMP) process to establish a desired or constant thickness, as further described herein, regarding FIG. 1, for example. For instance, layer 1102 of deposited and/or patterned SiO₂ 108 can be patterned (e.g., via lithography, etch) as depicted 1200 in FIG. 12 to define portions 1202 of anchor structures 128 associated with exemplary spring pillar, portions 1204 of center column structure 132, and portions 1206 of lateral etch stop that can define a cavity or chamber between sensing membrane structure 110 and backplate structure 114.

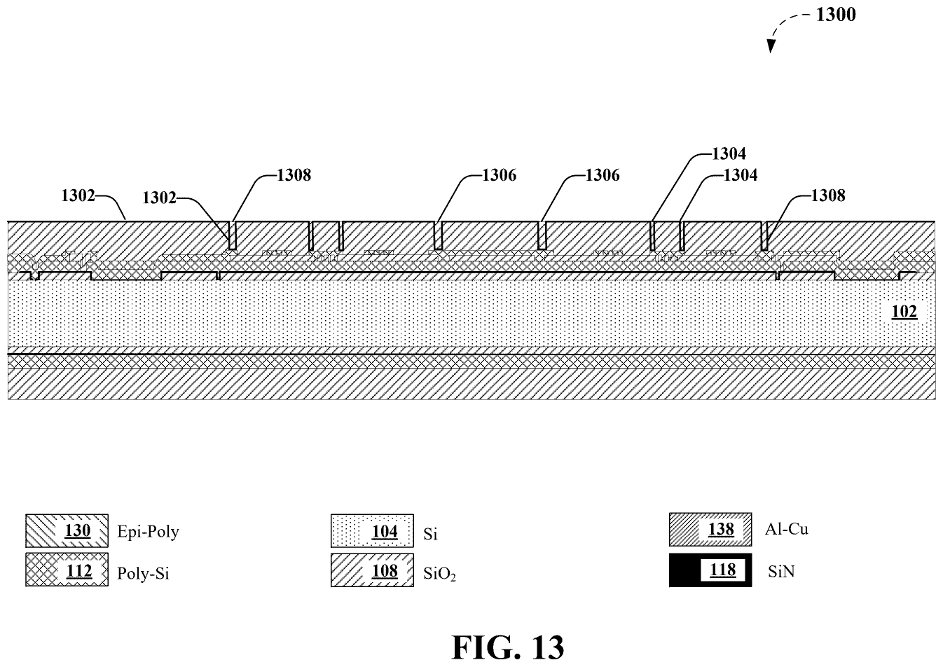

In another non-limiting example, FIG. 13 depicts 1300 exemplary MEMS device or sensor 100 undergoing fabrication processes in which a layer 1302 comprising a layer of deposited and/or patterned SiN 118 can be deposited on top of the patterned sacrificial layer 1102, as further described herein, regarding FIG. 1, for example. In addition, FIG. 13 depicts 1300 exemplary MEMS devices or sensors 100 undergoing fabrication processes in which a layer of deposited and/or patterned SiO₂ 108 is grown over deposited and/or patterned SiN 118. Exemplary MEMS devices or sensors 100 can then undergo a CMP process to the layer 1302 comprising a layer of deposited and/or patterned SiN 118, such that portions 1304 of anchor structures 128 associated with exemplary spring pillar, portions 1306 of center column structure 132, and portions 13068 of lateral etch stop are filled with SiO₂ 108.

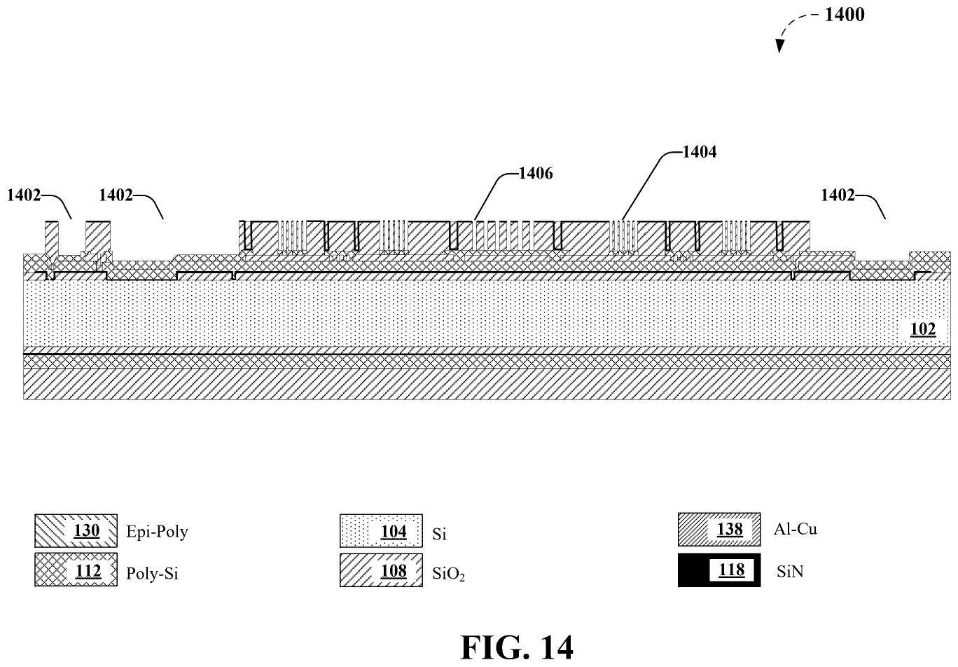

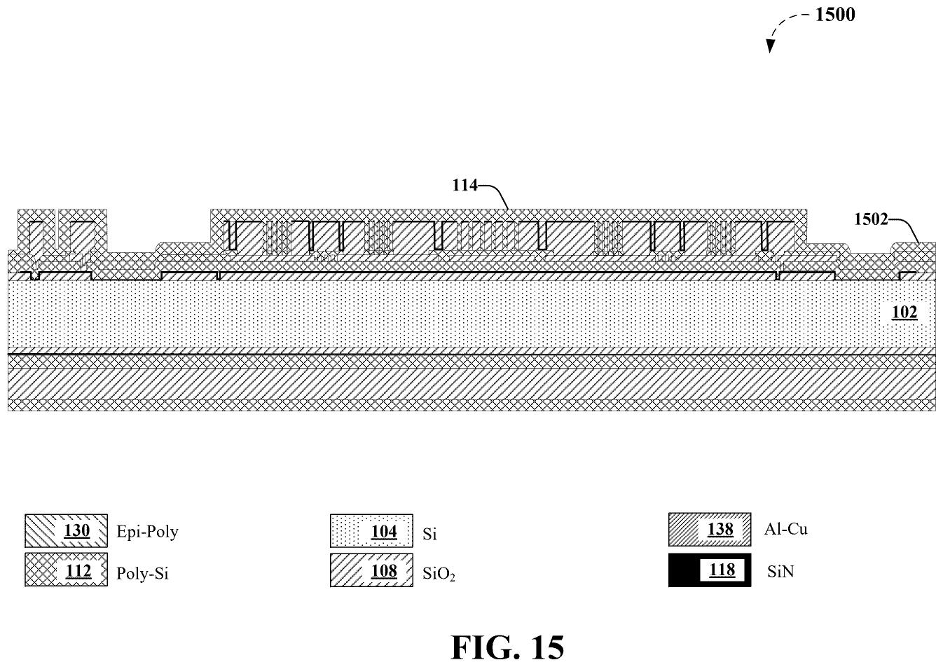

In a further non-limiting example, FIG. 14 depicts 1400 exemplary MEMS device or sensor 100 having undergone fabrication processes in which layer 1302 was etched to establish locations for the fabrication of contact vias 1402, for example, as further described herein, regarding FIG. 1. In addition, FIG. 14 further depicts 1400 established locations for poly-Si 112 deposition at portions 1404 of electrodes 116 and portions 1406 of center column structure 132. For instance, FIG. 15 depicts 1500 exemplary MEMS devices or sensors 100 undergoing fabrication processes in which a layer 1502 of deposited and/or patterned poly-Si 112 can be developed to form backplate structure 114, portions of contact vias 1402, portions 1404 of electrodes 116, and portions 1406 of center column structure 132.

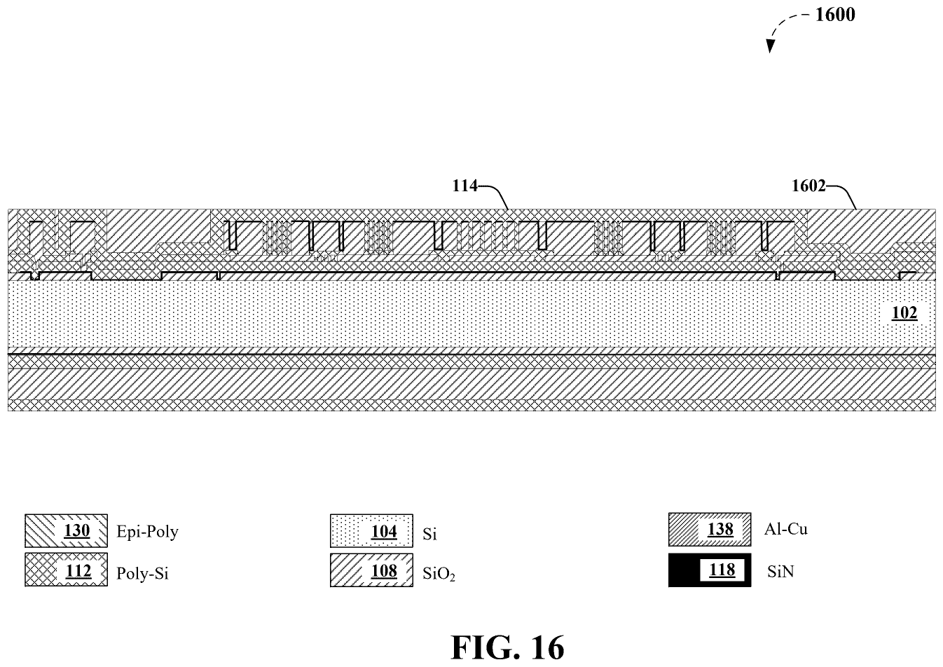

In another non-limiting example, FIG. 16 depicts 1600 exemplary MEMS devices or sensors 100 undergoing fabrication processes in which a layer 1602 of deposited and/or patterned SiO₂ 108, can be developed over layer 1502 of deposited and/or patterned poly-Si 112. Exemplary MEMS devices or sensors 100 can then undergo a CMP process to establish a desired or constant thickness, as further described herein, regarding FIG. 1, for example, while exposing layer 1502 of deposited and/or patterned poly-Si 112 for backplate structure 114, and so on.

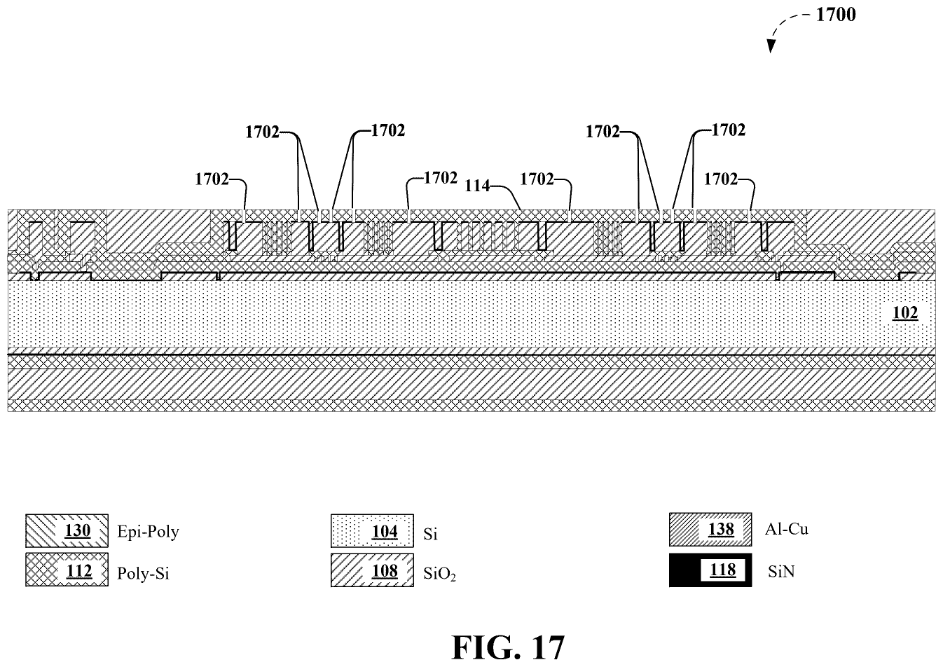

As further depicted 1700 in FIG. 17, a set of etch release structures 1702 can be defined and/or patterned in backplate structure 114 layer of deposited and/or patterned poly-Si 112 and configured to enable a uniform etch of the sacrificial layers 902 and 1102 in the area or cavity of the exemplary MEMS devices or sensors 100 between the sensing membrane structure 110 and the electrodes 116, backplate structure 114, and so on. In still further non-limiting aspects of exemplary MEMS devices or sensors 100, the number, position, and arrangement of the set of passages of the set of etch release structures 1702 in the backplate structure 114 can vary (e.g., in size, number, location), without limitation.

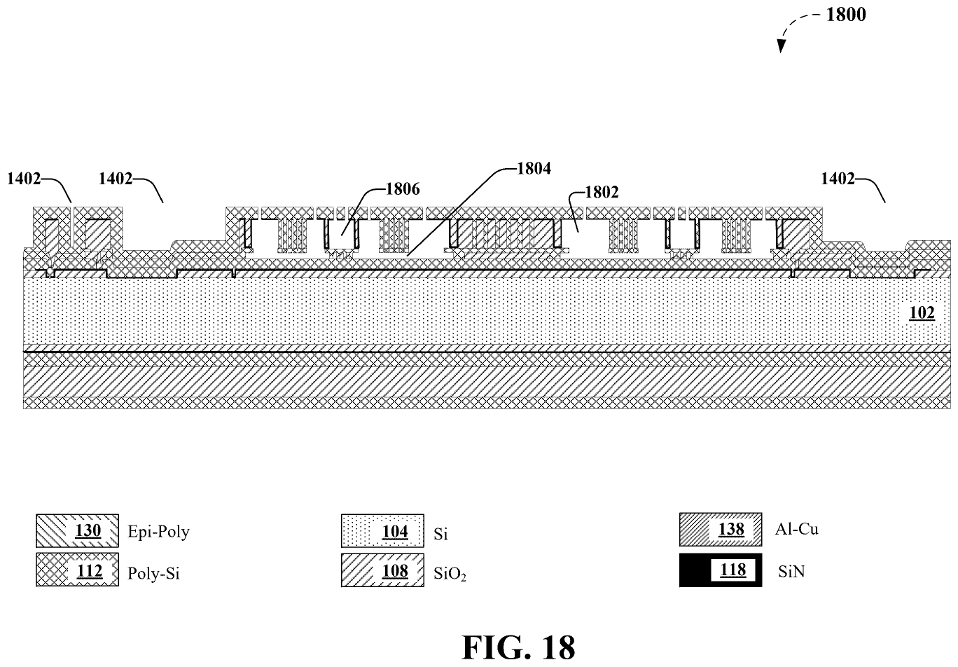

In addition, FIG. 18 depicts 1800 exemplary MEMS device or sensor 100 undergoing fabrication processes in which a release etch can be performed of the sacrificial layers 902 and 1102 in the area of the cavity or chamber 1802 between sensing membrane structure 110 and backplate structure 114 of the exemplary MEMS devices or sensors 100, the areas 1804 between the sensing membrane structure 110 and the electrodes 116, and areas 1806 associated with the anchor structures 128, as well as in areas of contact vias 1402, as further described herein, regarding FIG. 1, for example.

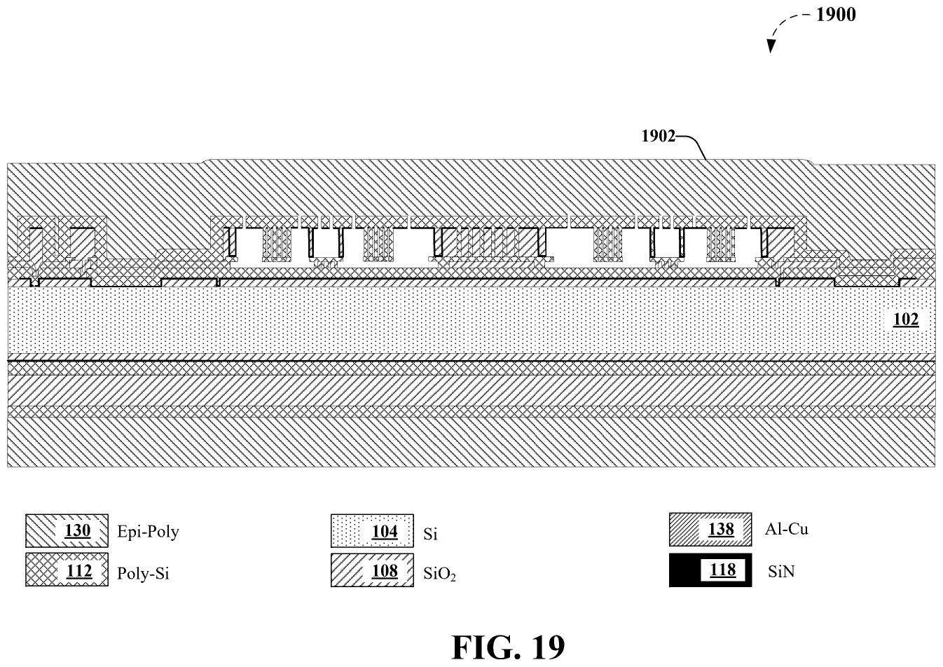

In another non-limiting example, FIG. 19 depicts 1900 exemplary MEMS device or sensor 100 undergoing fabrication processes in which pressure of the cavity between the sensing membrane structure 110 and the backplate structure 114 can be established and/or etch release structures 1702 sealing can be established, comprising one or more layers 1902 of deposited and/or patterned epi-poly-Si 130, thus sealing the cavity or chamber, as further described herein, regarding FIG. 1. As further described herein, in still another non-limiting example, where processes are described as employing a deposition of epi-poly-Si 130, for instance, to seal a chamber in exemplary MEMS devices that is exposed via release etching, it can be understood that other suitable materials such as SiN 112, SiO₂ 108, metal 138, or another suitable material can be employed to facilitate sealing of such a chamber at a predetermined chamber pressure. In another non-limiting embodiment, layer 1902 of deposited and/or patterned epi-poly-Si 130 can be patterned (e.g., via lithography, etch) (not shown) to expose portions associated with contact vias 1402 for electrical coupling of portions of exemplary MEMS device or sensor 100, as further described herein.

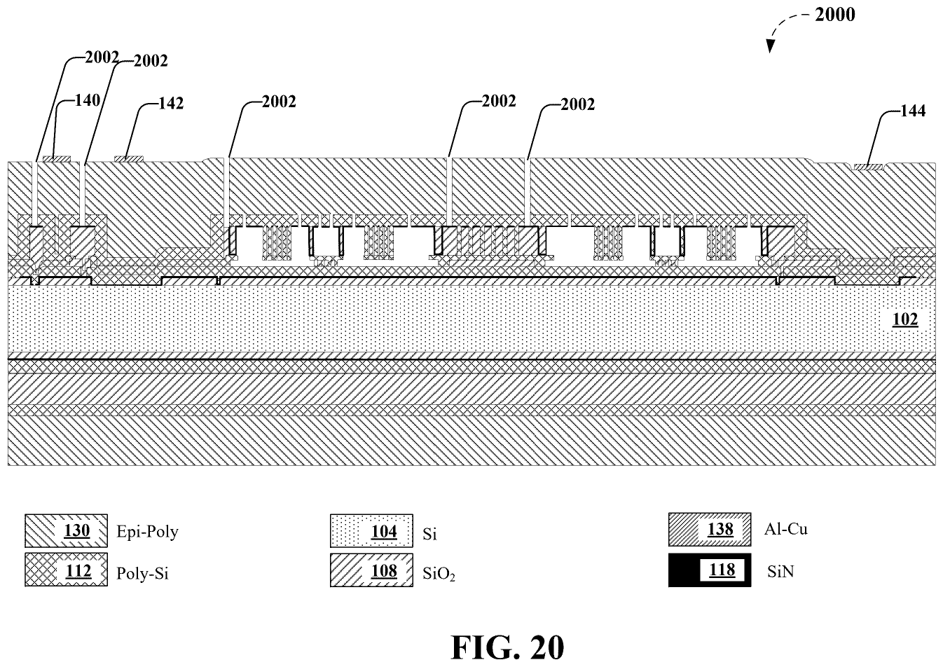

In a further non-limiting example, FIG. 20 depicts 2000 exemplary MEMS device or sensor 100 undergoing fabrication processes in which contact areas 2002 for the fixed electrode structure 108 can be deposited, patterned, and etched, as further described herein, regarding FIG. 1, for example. Thus, FIG. 20 depicts 2000 exemplary MEMS device or sensor 100 undergoing fabrication processes in which one or more layers of deposited and/or patterned metal 138 (e.g., Al—Cu 138) can form one or more of substrate contact pad 140, sensing membrane structure 110 contact pad 142, and/or backplate structure 114 contact pad 144. In addition, FIG. 20 further depicts 2000 layer 1902 of deposited and/or patterned epi-poly-Si 130 patterned (e.g., via lithography, etch) for electrical isolation 2002 of portions of exemplary MEMS device or sensor 100 (e.g., substrate 102, sensing membrane 110, and backplate portion 114), as further described herein, associated with respective substrate contact pad 140, sensing membrane structure 110 contact pad 142, and/or backplate structure 114 contact pad 144.

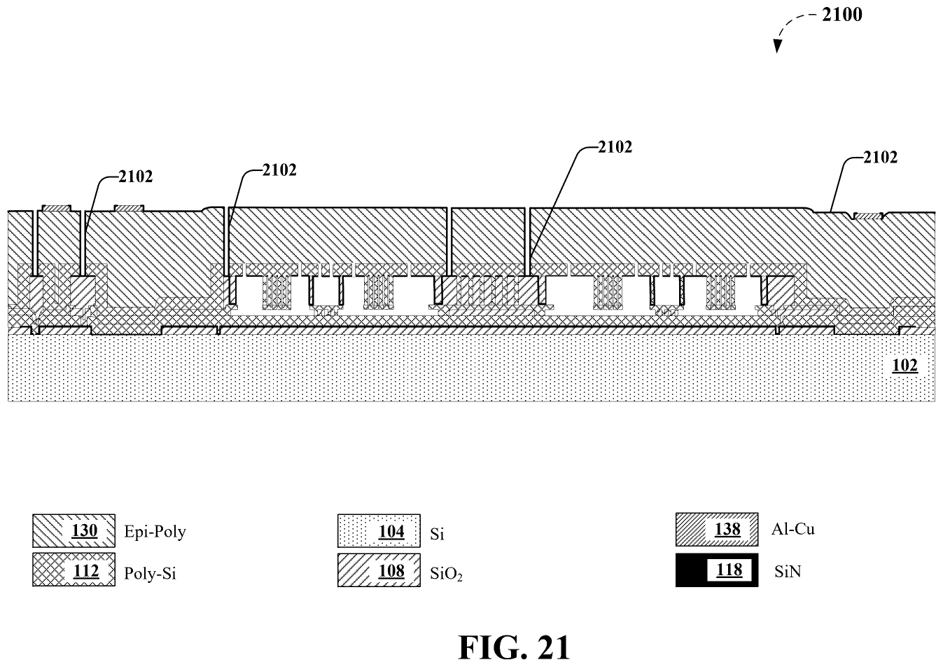

In another non-limiting example, FIG. 21 depicts 2100 exemplary MEMS device or sensor 100 undergoing fabrication processes in which a passivation layer 2102 comprising a layer of deposited and/or patterned SiN 118 can be deposited on top of the deposited and/or patterned epi-poly-Si 130, which can in turn be patterned to expose and/or define substrate contact pad 140, sensing membrane structure 110 contact pad 142, and/or backplate structure 114 contact pad 144, as further described herein, regarding FIG. 1, for example. In a further non-limiting example, FIG. 21 depicts 2100 exemplary MEMS device or sensor 100 undergoing fabrication processes in which exemplary MEMS device or sensor 100 can be reduced in thickness on the back side of the exemplary MEMS device or sensor 100 substrate 102, such as by undergoing a CMP process to establish a desired or constant thickness (e.g., to expose substrate 102), prior to fabricating a cavity or port for the exemplary MEMS device or sensor 100.

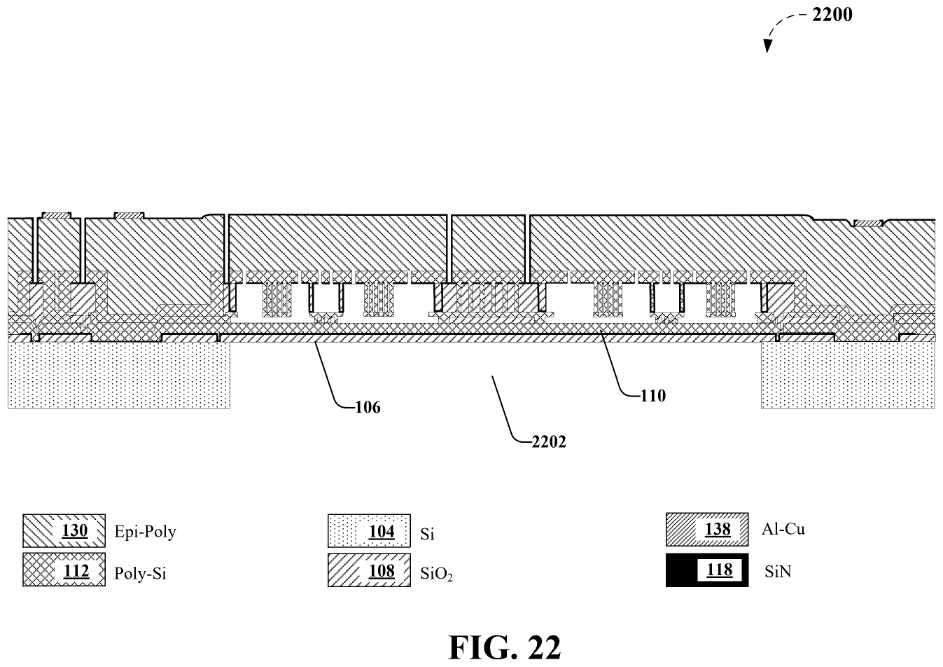

For instance, FIG. 22 further depicts 2200 exemplary MEMS device or sensor 100 undergoing fabrication processes in which substrate 102 can be patterned (e.g., via lithography, etch) to define and fabricate a cavity or port 2202 for the exemplary MEMS device or sensor 100 to receive an external input at the sensing membrane structure 110. In a non-limiting aspect, an exemplary etch process for the cavity or port 2202 for the exemplary MEMS device or sensor 100 can proceed to the device insulating layer 106.

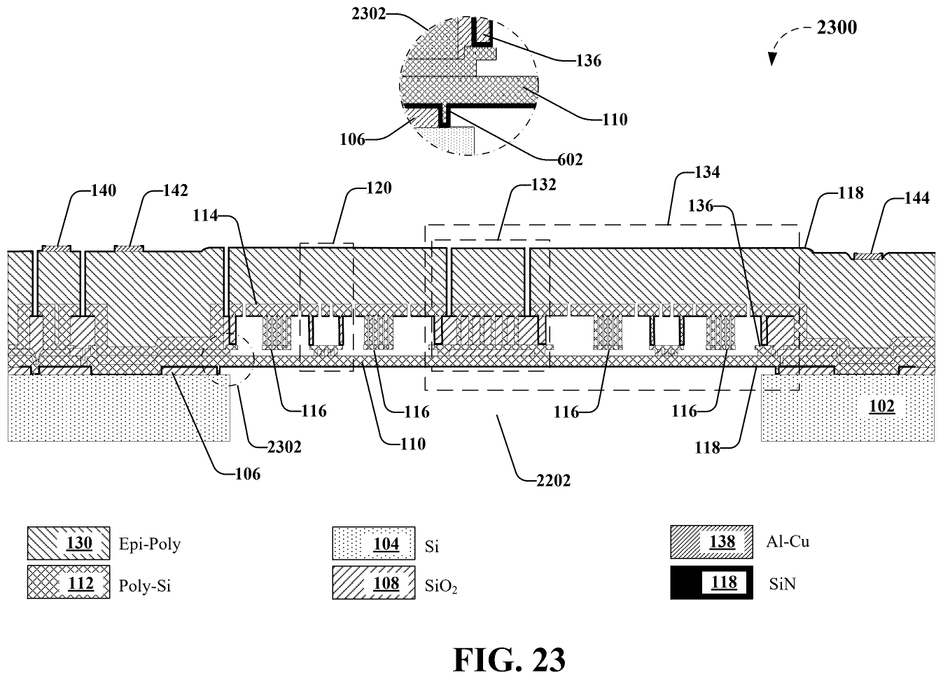

In addition, FIG. 23 depicts 2300 exemplary MEMS device or sensor 100 undergoing fabrication processes in which a release etch of the sensing membrane structure 110 in the area of the cavity or port 2202 and between sensing membrane structure 110 substrate 102 in the areas of the sensing membrane structure 110 and the sensing membrane structure 110 lateral etch stop 602 (e.g., as depicted 2302 in detail) can facilitate allowing an external input to be sensed by and cause deformation of sensing membrane structure 110, as further described herein, regarding FIG. 1, for example.

In still other non-limiting embodiments, FIG. 24 provides a cross-section of exemplary MEMS devices or sensors 2400 comprising an exemplary pillar structure and an exemplary spring membrane structure that depicts various non-limiting aspects described herein. For the sake of brevity and as an aid to understanding various embodiments described herein, like numbers and descriptions of functional or structural aspects of the exemplary MEMS devices or sensors 2400 are provided as that for exemplary MEMS devices or sensors 100 depicted in FIG. 1. It is to be understood that various modifications can be made to either of exemplary MEMS devices or sensors 100 or exemplary MEMS devices or sensors 2400, for example, such as by modifying various details in respective FIGS. 1-23 or FIGS. 24-43, without departing from the scope of the recited claims. Thus, exemplary MEMS devices or sensors 2400 of FIG. 24 and FIGS. 25-43 represent another non-limiting implementation of exemplary MEMS devices or sensor employing exemplary spring pillar or flexible pillar, with the backplate structure 114 adjacent to the substrate 102, as described herein, and with electrode 116 comprising a wiring electrode 2402 electrically coupled to a facing electrode 2404.

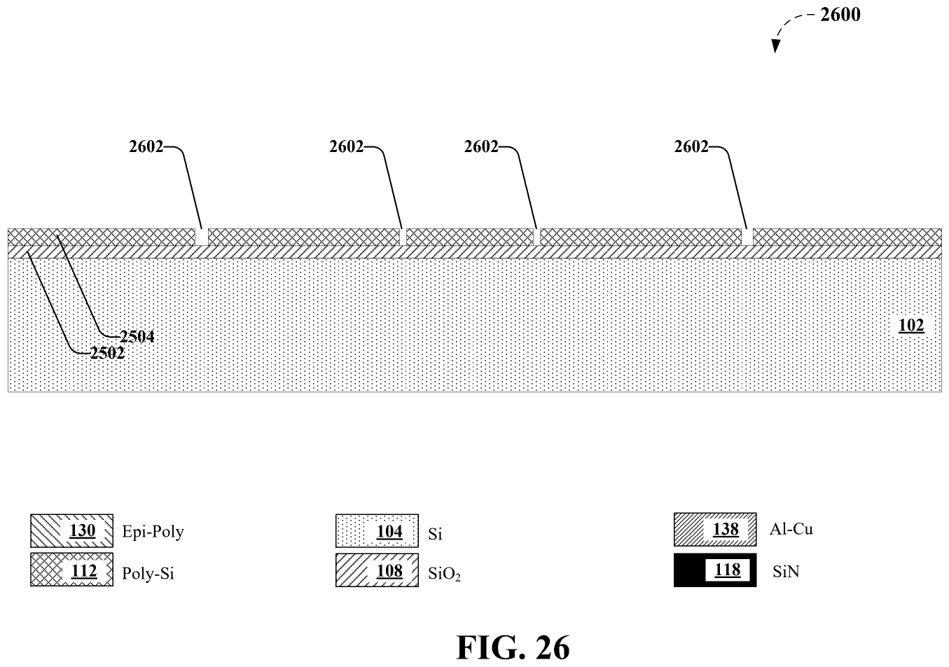

Accordingly, FIGS. 25-43 illustrate example, non-limiting, cross-sectional views of further exemplary MEMS devices or sensors comprising an exemplary pillar structure and an exemplary spring membrane structure undergoing fabrication processes in accordance with one or more embodiments described herein. For instance, FIG. 25 depicts 2500 exemplary MEMS device or sensor 2400 undergoing fabrication processes in which an exemplary device substrate 102 (e.g., a wafer substrate, a silicon 104 wafer) receives a device insulating layer 106 comprising a layer 2502 of deposited and/or patterned SiO₂ 108, as further described herein, regarding FIGS. 1, 24. In a further non-limiting example, FIG. 26 depicts 2600 exemplary MEMS device or sensor 2400 undergoing fabrication processes in which a backplate structure 114 (e.g., wiring electrode 2402) comprising a layer 2504 of deposited and/or patterned poly-Si 112 can be deposited/patterned over layer 702 of SiN 118, as further described herein, regarding FIG. 1.

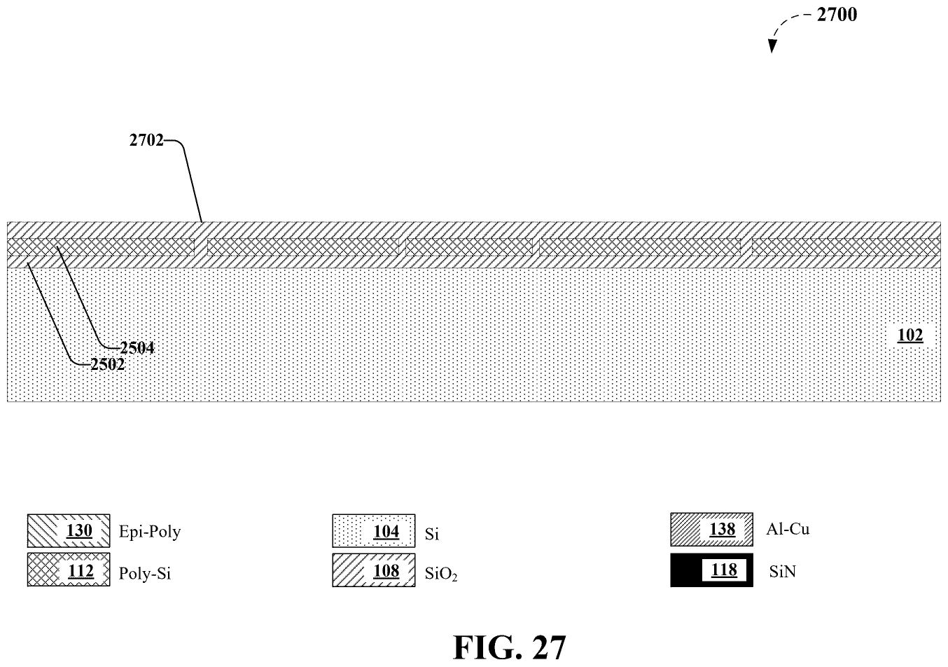

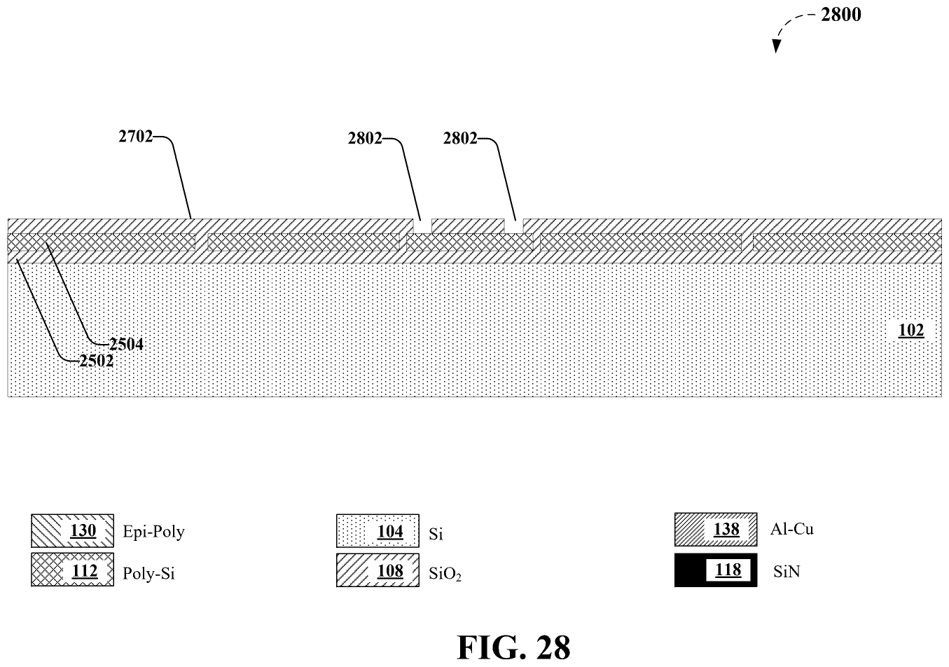

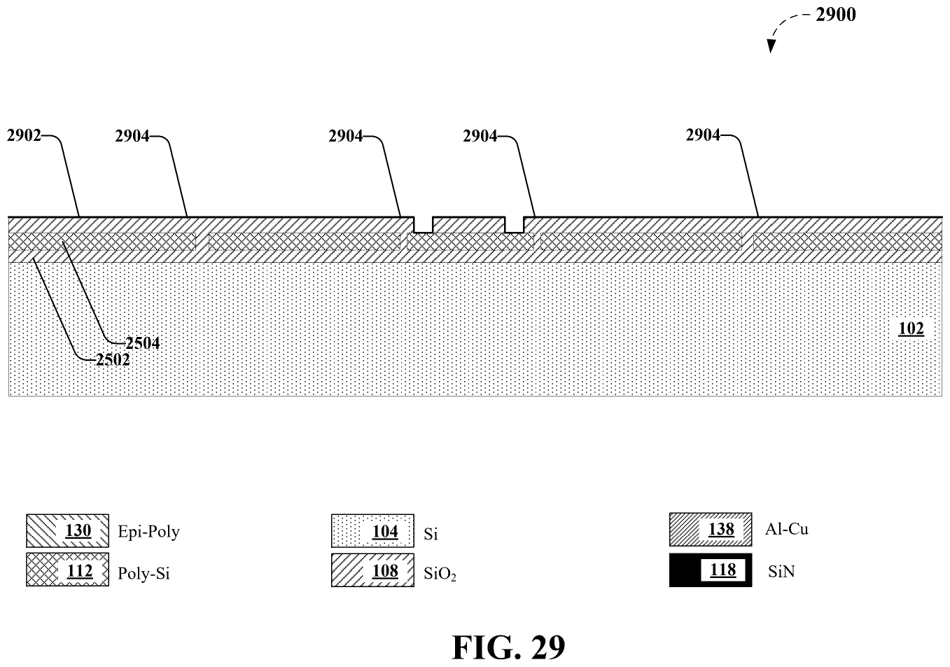

In addition, FIG. 26 depicts 2600 exemplary MEMS devices or sensors 2400 undergoing fabrication processes in which a layer 2504 of deposited and/or patterned poly-Si 112 can be patterned (e.g., via lithography, etch) to define portions 2602 of wiring electrodes 2402. In another non-limiting example, FIG. 27 depicts 2700 exemplary MEMS devices or sensors 2400 undergoing fabrication processes in which a layer 2702 of deposited and/or patterned SiO₂ 108, can be developed over the backplate structure 114 (e.g., wiring electrode 2402) comprising layer 2504 of deposited and/or patterned poly-Si 112, as further described herein. In another non-limiting aspect, FIG. 28 depicts 2800 exemplary MEMS devices or sensors 2400 undergoing fabrication processes in which layer 2702 of deposited and/or patterned SiO₂ 108 can be patterned (e.g., via lithography, etch) to define portions 2802 of anchor structures 122 associated with exemplary spring pillar or flexible pillar. In another non-limiting example, FIG. 29 depicts 2900 exemplary MEMS device or sensor 2900 undergoing fabrication processes in which a layer 2902 comprising a layer of deposited and/or patterned SiN 118 can be deposited on top of layer 2702 of deposited and/or patterned SiO₂ 108, as further described herein, regarding FIG. 1, for example, to define portions 2904 for release etch stop.

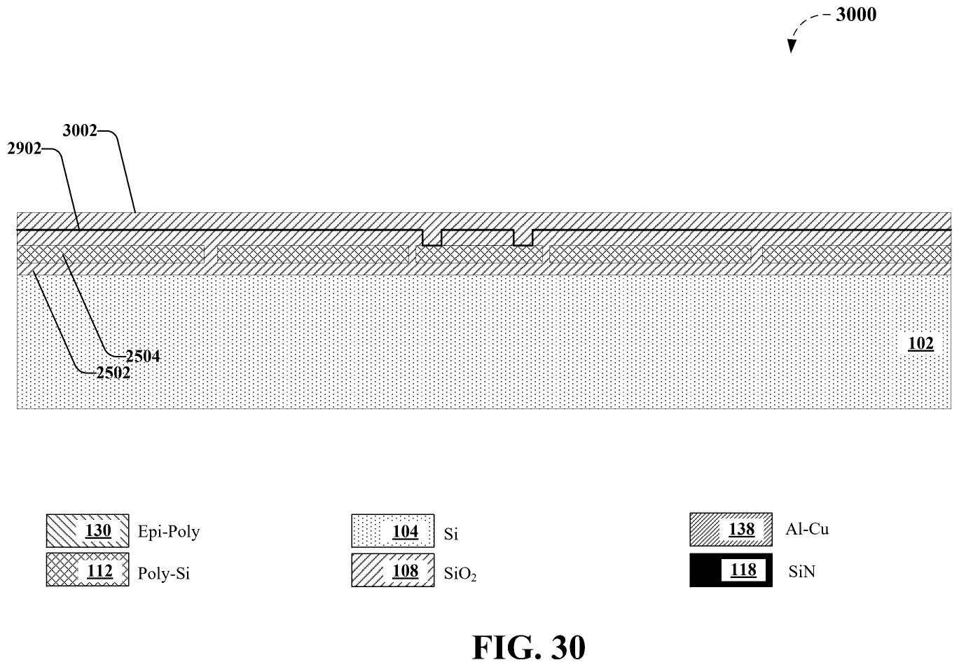

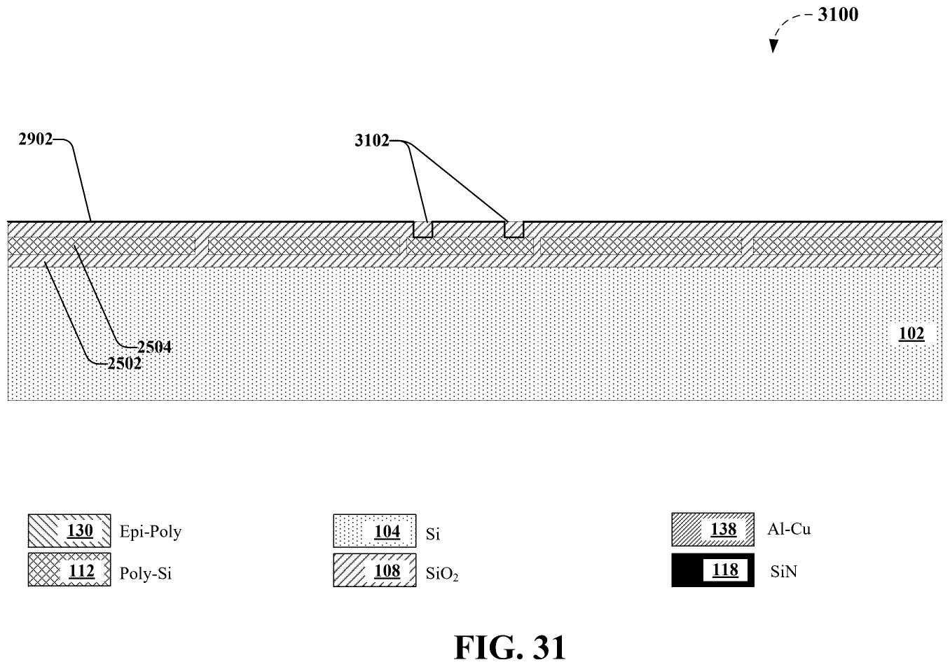

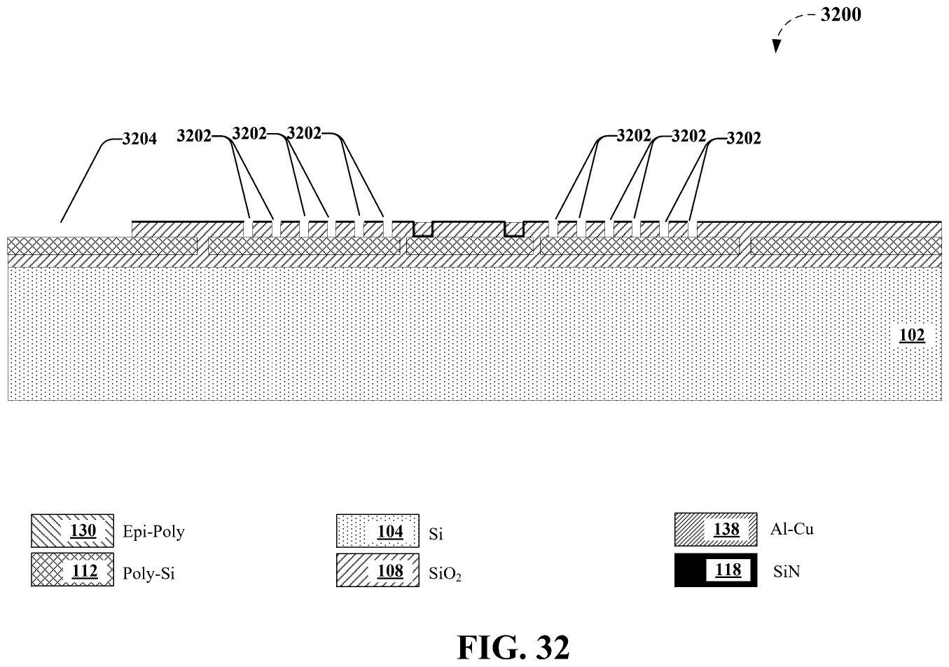

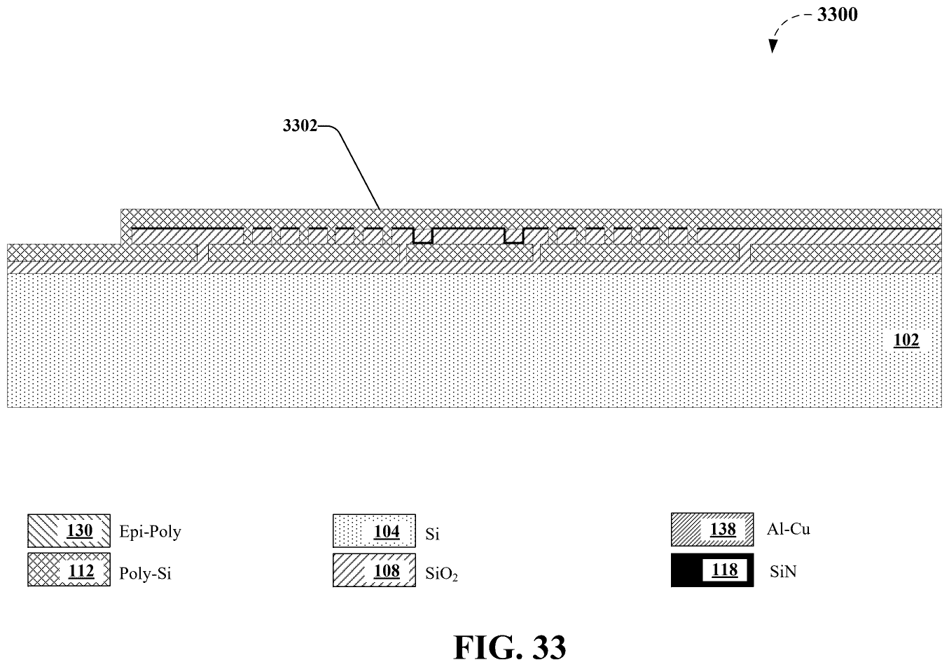

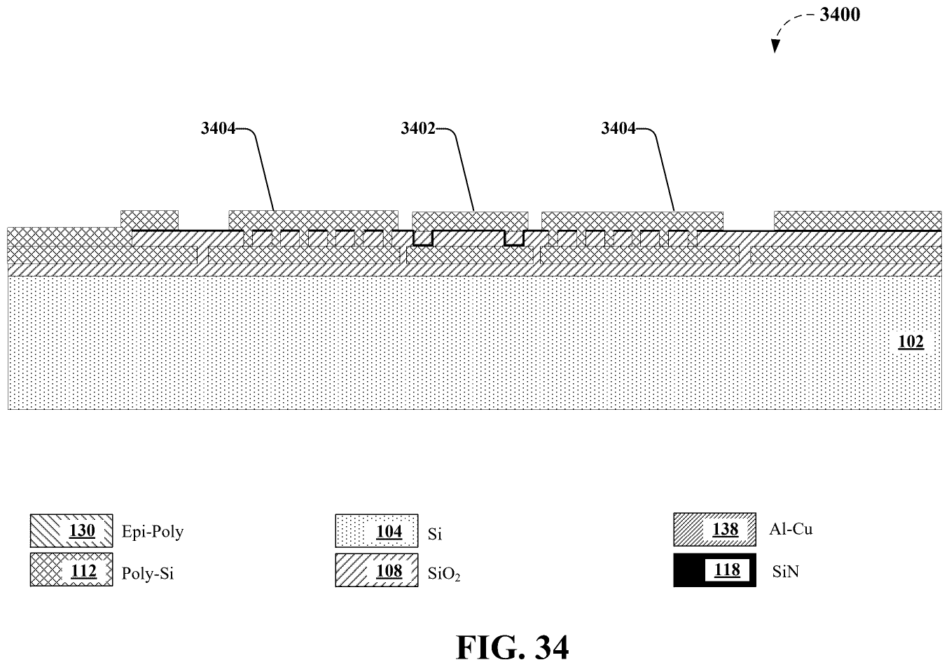

In another non-limiting example, FIG. 30 depicts 3000 exemplary MEMS devices or sensors 2400 undergoing fabrication processes in which a layer 3002 of deposited and/or patterned SiO₂ 108, can be developed over layer 2902 of deposited and/or patterned SiN 118. As further depicted 3100 in FIG. 31, exemplary MEMS devices or sensors 2400 can then undergo a CMP process to layer 2902 comprising a layer of deposited and/or patterned SiN 118, such that portions 3102 of anchor structures 128 associated with exemplary spring pillar are filled with SiO₂ 108. In a further non-limiting example, FIG. 32 depicts 3200 exemplary MEMS device or sensor 3200 having undergone fabrication processes in which layer 2902 and 2702 was etched to establish locations for the fabrication of contact vias 3202 from wiring electrodes 2402 to facing electrodes 2404 as well as contact via 3204 for the backplate structure 114 contact pad 144, for example, as further described herein, regarding FIG. 1. In addition, FIG. 33 further depicts 3300 exemplary MEMS device or sensor 3200 having undergone fabrication processes in which layer 3302 of deposited and/or patterned poly-Si 112 can be developed to facing electrodes 2404. Thus, FIG. 34 depicts 3400 exemplary MEMS devices or sensors 2400 undergoing fabrication processes in which layer 3302 of deposited and/or patterned poly-Si 112 can be patterned (e.g., via lithography, etch) to define portions 3402 of spring membrane 126 associated with exemplary spring pillar and portions 3404 of facing electrodes 2404.

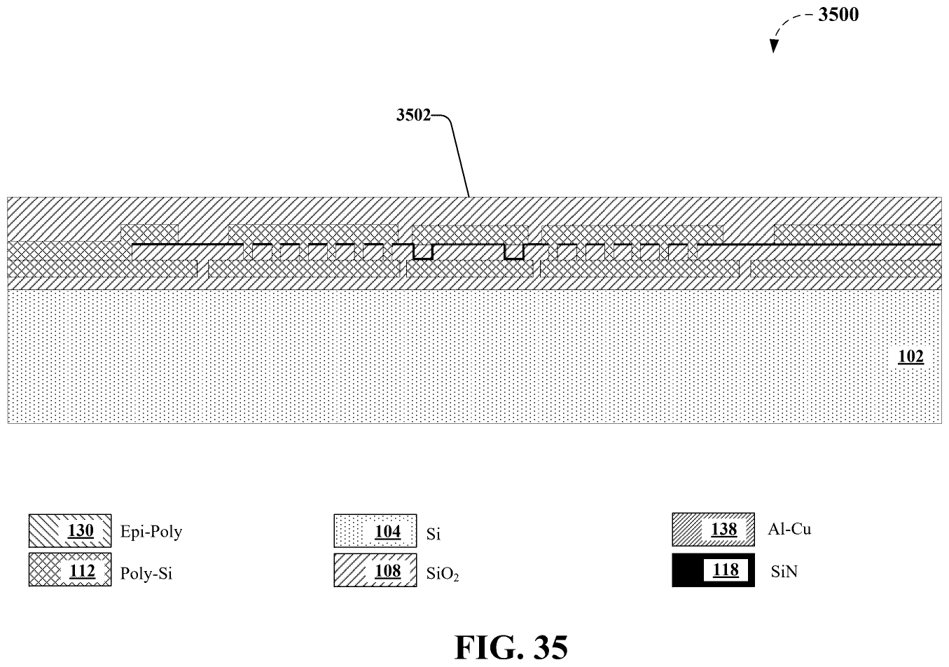

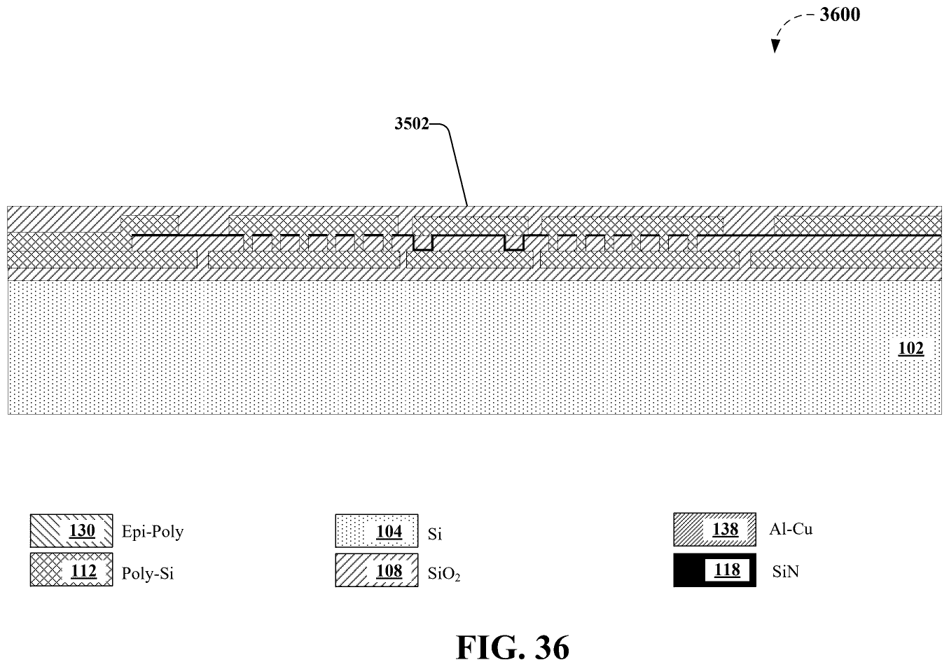

In another non-limiting example, FIG. 35 depicts 3500 exemplary MEMS devices or sensors 2400 undergoing fabrication processes in which a layer of deposited and/or patterned SiO₂ 108, can be developed as a sacrificial layer 3502 over the facing electrodes 2404 and under the sensing membrane structure 110, thereby defining the gap between such structures, and portions of which sacrificial layer 3502 can be release etched as further described herein to define, in part, the cavity, chamber, or gap therebetween. As depicted 3600 in FIG. 36, exemplary MEMS devices or sensors 3600 can then undergo a CMP process to establish a desired or constant thickness, as further described herein, regarding FIG. 1, for example, thereby defining the gap between the sensing membrane structure 110 and the facing electrodes 2404, for example, and portions of which layer 3502 can be release etched as further described herein to define, in part, the cavity, chamber, or gap therebetween.

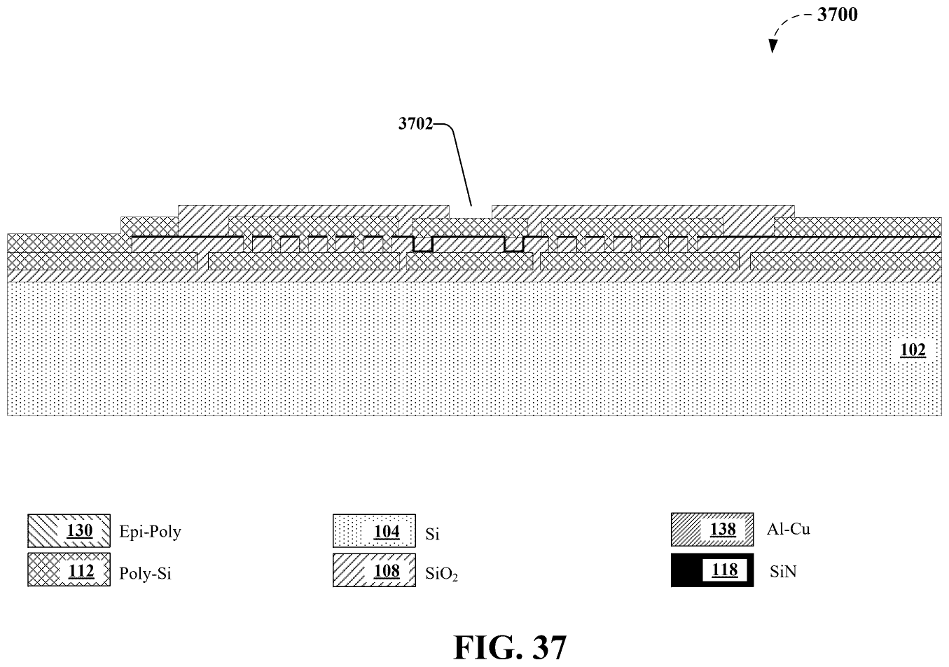

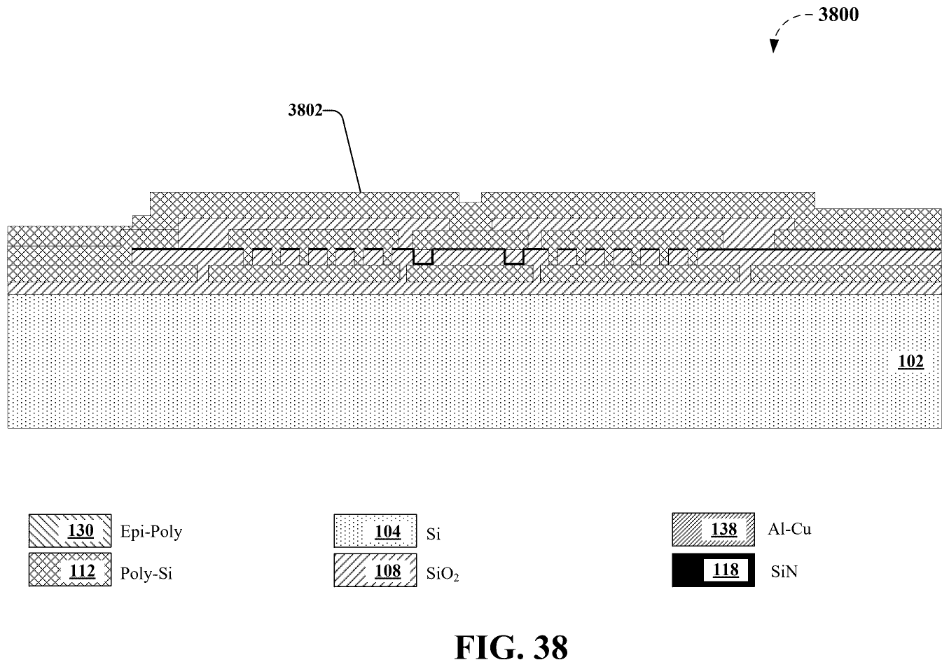

In addition, sacrificial layer 3502 of deposited and/or patterned SiO₂ 108 can be patterned (e.g., via lithography, etch) as depicted 3700 in FIG. 37 to define portions 3702 of pillar structure 122 associated with exemplary spring pillar, as further described herein. In still further non-limiting embodiments, FIG. 38 depicts 3800 exemplary MEMS device or sensor 2400 undergoing fabrication processes in which sensing membrane structure 110 comprising a layer 3802 of deposited and/or patterned poly-Si 112 can be deposited/patterned over sacrificial layer 3502 of SiO₂ 108, as further described herein.

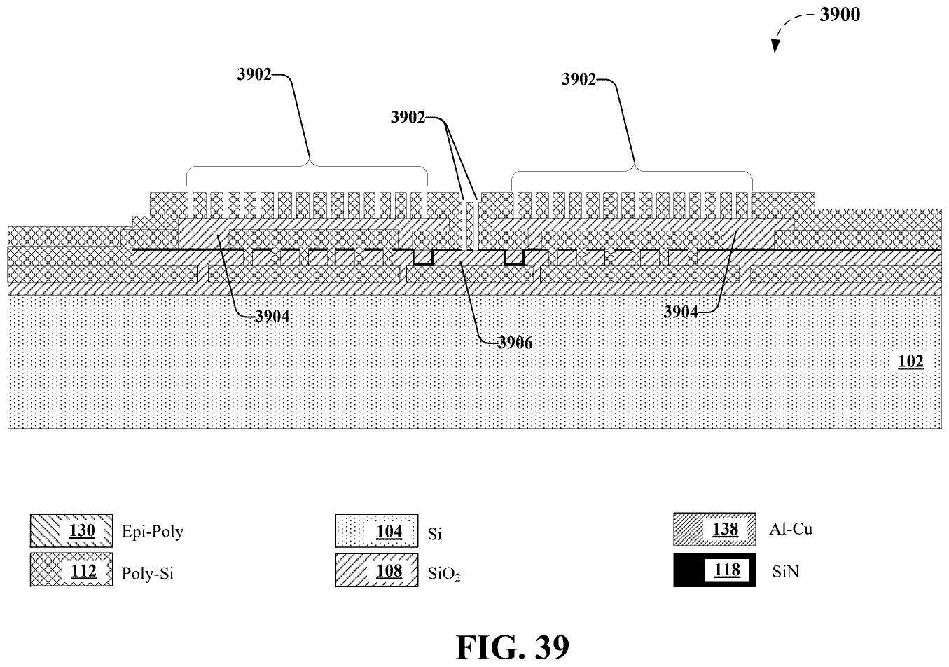

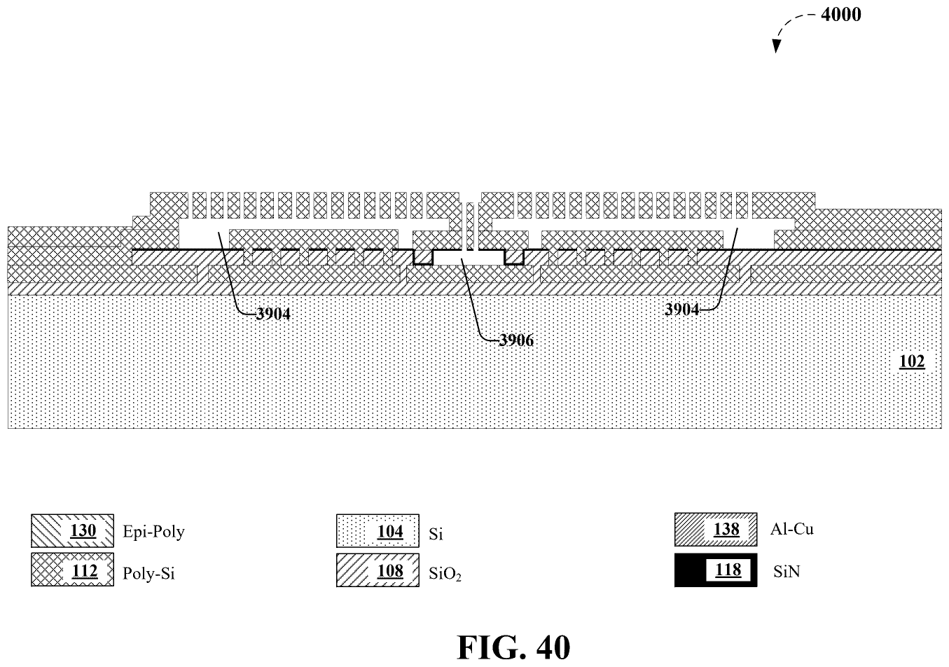

As further depicted 3900 in FIG. 39, a set of etch release structures 3902 can be defined and/or patterned in sensing membrane structure 110 layer 3802 of deposited and/or patterned poly-Si 112 and configured to enable a uniform etch of sacrificial layer 3502 in the area of cavity or chamber 3904 of the exemplary MEMS devices or sensors 100 between the sensing membrane structure 110 and wiring electrodes 2402 and facing electrodes 2404, in the area 3906 beneath spring membrane 126, and so on. In still further non-limiting aspects of exemplary MEMS devices or sensors 100, the number, position, and arrangement of the set of passages of the set of etch release structures 3902 in the sensing membrane structure can vary (e.g., in size, number, location), without limitation. In addition, FIG. 40 depicts 4000 exemplary MEMS device or sensor 2400 undergoing fabrication processes in which a release etch can be performed of sacrificial layer 3502 in the area of the cavity or chamber 3904 of the exemplary MEMS devices or sensors 100 between the sensing membrane structure 110 and wiring electrodes 2402 and facing electrodes 2404, in the area 3906 beneath spring membrane 126, and so on, as further described herein.

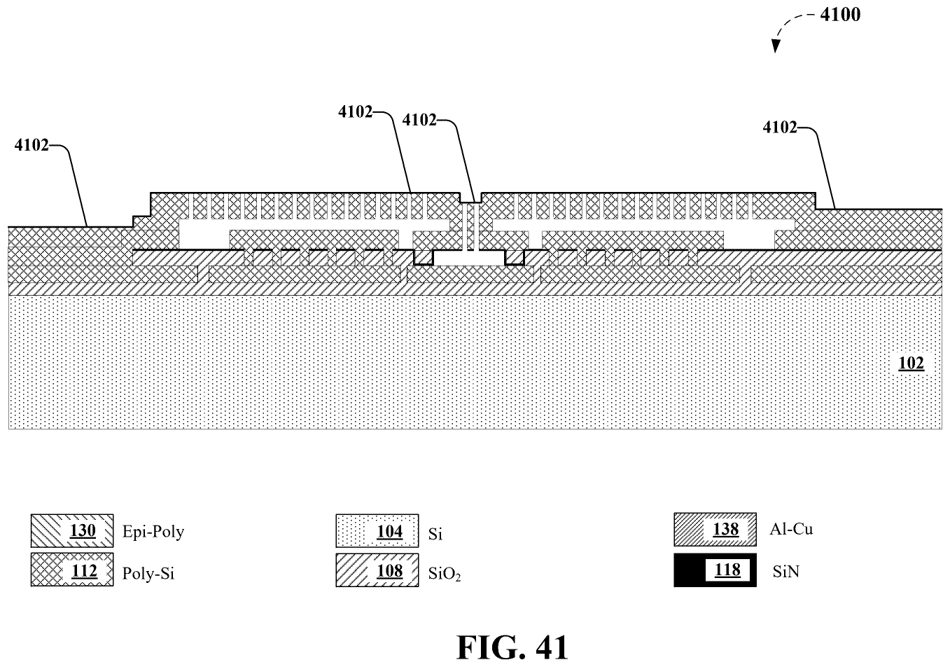

In another non-limiting example, FIG. 41 depicts 4100 exemplary MEMS device or sensor 2400 undergoing fabrication processes in which pressure of the cavity between the sensing membrane structure 110 and the backplate structure 114 can be established and/or etch release structures 1702 sealing can be established, comprising one or more layers 4102 of deposited and/or patterned SiN 118, thus sealing the cavity or chamber, as further described herein, regarding FIG. 1. As further described herein, in still another non-limiting example, where processes are described as employing a deposition of SiN 112, for instance, to seal a chamber in exemplary MEMS devices that is exposed via release etching, it can be understood that other suitable materials such as SiO₂ 108, metal 138, or another suitable material, such as epi-poly-Si 130, can be employed to facilitate sealing of such a chamber at a predetermined chamber pressure.

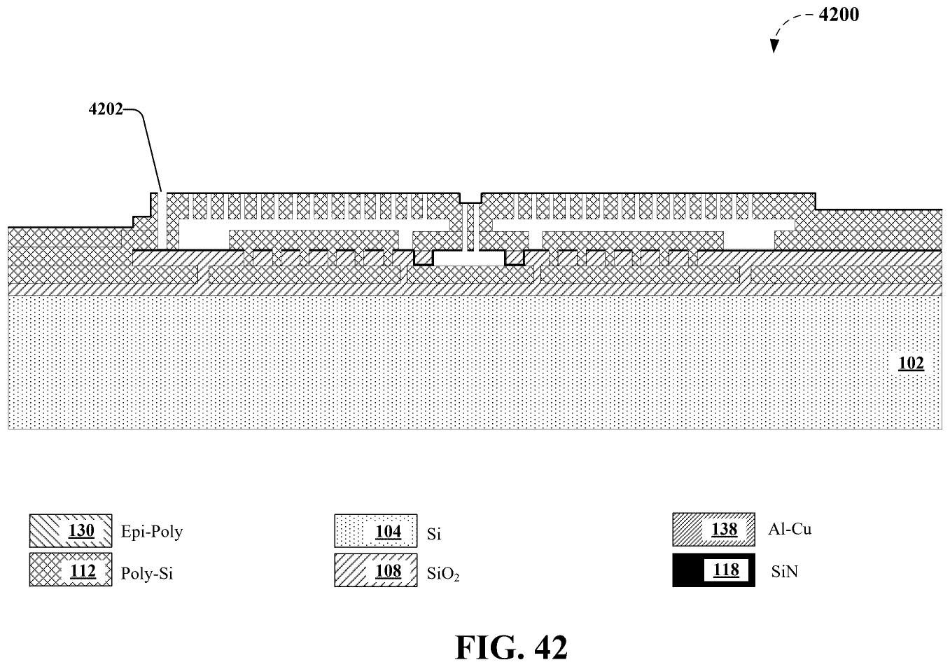

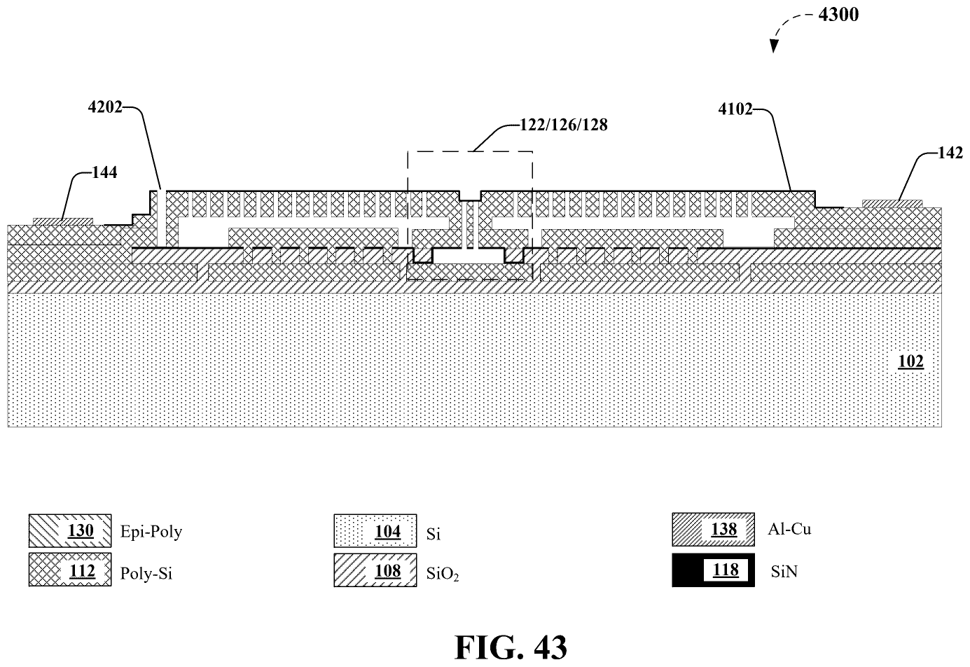

In addition, FIG. 42 further depicts 4200 layer 3802 of deposited and/or patterned epi-poly-Si 130 patterned (e.g., via lithography, etch) for electrical isolation 4202 of portions of exemplary MEMS device or sensor 2400 (e.g., e.g., substrate 102, sensing membrane 110, and backplate portion 114), as further described herein, associated with respective sensing membrane structure 110 contact pad 142 and/or backplate structure 114 contact pad 144, for example, as further described herein. In further non-limiting embodiments, FIG. 43 depicts 4300 exemplary MEMS device or sensor 2400 undergoing fabrication processes in which one or more layers of deposited and/or patterned metal 138 (e.g., Al—Cu 138) can form one or more of substrate contact pad (not shown), sensing membrane structure 110 contact pad 142, and/or backplate structure 114 contact pad 144, as further described herein.

FIG. 44 illustrates 4400 further aspects of non-limiting embodiments comprising an exemplary pillar structure 122 and an exemplary spring membrane 128 structure suitable for use in exemplary MEMS devices or sensors 100/2400 described herein. For instance, referring again to FIG. 5, MEMS devices or sensors 100 (e.g., comprising a pressure sensor, an acoustic sensor, an ultrasonic sensor) were described as able to comprise a donut-shaped sensing membrane structure 110 of a sealed-cavity, vacuum chamber, capacitive sensing device, that can provide large sensing area, robustness to large external loads, and sensitivity to small pressure level variations, and adjustable compliance of sensing membrane structure 110 (e.g., for a given external input), by incorporating various aspects described herein. However, it can be appreciated that the disclosed embodiments are not so limited. Thus, FIG. 44 depicts 4400 further aspects of non-limiting embodiments comprising an exemplary pillar structure 122 and an exemplary spring membrane 128 structure suitable for use in exemplary MEMS devices or sensors 100/2400 described herein. For instance, FIG. 44 demonstrates that exemplary circular spring pillar or flexible pillar, as described herein, can include exemplary circular spring pillar or flexible pillar associated with exemplary pillar structure 122 and an exemplary spring membrane 128 for a circular 4402 sensing membrane structure 110 and exemplary circular spring pillar or flexible pillar associated with exemplary pillar structure 122 and an exemplary spring membrane 128 for a circular 4404 sensing membrane structure 110, and so on, without limitation.

Accordingly, various non-limiting embodiments of the disclosed subject matter can provide an exemplary MEMS apparatus (e.g., MEMS device or sensor 100/2400) that can comprise a sensing membrane structure (e.g., sensing membrane structure 110) that can be configured to deform when exposed to an external input, for example, as further described herein regarding FIGS. 1, 5 and 6-44. In a non-limiting aspect, exemplary MEMS apparatus (e.g., MEMS device or sensor 100/2400) can comprise a sensing membrane structure (e.g., sensing membrane structure 110) that can comprise one or more of a circular shape, a donut shape, or a rectangular shape, and wherein the spring membrane structure (e.g., spring membrane structure 124) can comprise a shape corresponding to the sensing membrane structure (e.g., sensing membrane structure 110), for example, as further described herein regarding FIGS. 5 and 44. In a further non-limiting aspect, exemplary MEMS apparatus (e.g., MEMS device or sensor 100/2400) can comprise a backplate structure (e.g., backplate structure 114).

In still further non-limiting aspects, exemplary MEMS apparatus (e.g., MEMS device or sensor 100/2400) can comprise a sealed cavity (e.g., sealed cavity or chamber 1802, sealed cavity or chamber 3904) located between the sensing membrane structure (e.g., sensing membrane structure 110) and the backplate structure (e.g., backplate structure 114), for example, as further described herein regarding FIGS. 18 and 39. In other non-limiting aspects, exemplary MEMS apparatus (e.g., MEMS device or sensor 100/2400) can be configured to respond to an external input that can comprise one or more of an acoustic pressure, an ultrasonic pressure, or an environmental pressure, and, as such, exemplary MEMS apparatus (e.g., MEMS device or sensor 100/2400) can comprise a capacitive MEMS sensor (e.g., such as a capacitive MEMS pressure sensor, a capacitive MEMS acoustic sensor, a capacitive MEMS ultrasonic sensor). In another non-limiting aspect, exemplary MEMS apparatus (e.g., MEMS device or sensor 100/2400) can comprise a sensing membrane structure (e.g., sensing membrane structure 110) that can comprise a piezoelectric material, including, but not limited to aluminum nitride (AlN), lead zirconate titanate (PZT), zinc oxide, polyvinylidene difluoride (PVDF), lithium niobate (LiNbO3), and the like. Accordingly, in still other non-limiting aspects, exemplary MEMS apparatus (e.g., MEMS device or sensor 100/2400) can be configured to respond to an external input that can comprise one or more of an acoustic pressure, an ultrasonic pressure, or an environmental pressure, and, as such, exemplary MEMS apparatus (e.g., MEMS device or sensor 100/2400) can comprise a piezoelectric MEMS sensor (e.g., such as a piezoelectric MEMS pressure sensor, a piezoelectric MEMS acoustic sensor, a piezoelectric MEMS ultrasonic sensor).

Still further non-limiting embodiments of an exemplary MEMS apparatus (e.g., MEMS device or sensor 100/2400) can comprise a pillar structure (e.g., pillar structure 122) coupled to one of the sensing membrane structure (e.g., sensing membrane structure 110) or the backplate structure (e.g., backplate structure 114), for example, as further described herein regarding FIGS. 1, 5, and 6-44. In a non-limiting aspect, exemplary MEMS apparatus (e.g., MEMS device or sensor 100/2400) can comprise a pillar structure (e.g., pillar structure 122) that can be coupled between the sensing membrane structure (e.g., sensing membrane structure 110) and the spring membrane structure (e.g., spring membrane structure 124), wherein an anchor structure (e.g., anchor structure 128) can be coupled between the spring membrane (e.g., spring membrane 126) and the backplate structure (e.g., backplate structure 114).

In addition, exemplary MEMS apparatus (e.g., MEMS device or sensor 100/2400) can comprise a pillar structure (e.g., pillar structure 122) that can be coupled between the sensing membrane structure (e.g., sensing membrane structure 110) and the spring membrane structure (e.g., spring membrane structure 124). In another non-limiting aspect, an exemplary anchor structure (e.g., anchor structure 128) can be coupled between the spring membrane (e.g., spring membrane 126) and the backplate structure (e.g., backplate structure 114).

Other non-limiting embodiments of an exemplary MEMS apparatus (e.g., MEMS device or sensor 100/2400) can comprise a spring membrane structure (e.g., spring membrane structure 124) comprising a spring membrane (e.g., spring membrane 126) and an anchor structure (e.g., anchor structure 128), for example, as further described herein regarding FIGS. 1, 5 and 6-44. In a non-limiting aspect, exemplary MEMS apparatus (e.g., MEMS device or sensor 100/2400) can comprise a pillar structure (e.g., pillar structure 122) that can be coupled between the one of the sensing membrane structure (e.g., sensing membrane structure 110) or the backplate structure (e.g., backplate structure 114) and the spring membrane (e.g., spring membrane 126). In a further non-limiting aspect, exemplary MEMS apparatus (e.g., MEMS device or sensor 100/2400) can comprise an anchor structure (e.g., anchor structure 128) that coupled between the spring membrane (e.g., spring membrane 126) and an other one of the sensing membrane structure (e.g., sensing membrane structure 110) or the backplate structure (e.g., backplate structure 114).

In still further non-limiting aspects, an exemplary MEMS apparatus (e.g., MEMS device or sensor 100/2400) comprising a spring membrane structure (e.g., spring membrane structure 124) and the pillar structure (e.g., pillar structure 122) can be configured to provide a predetermined level of stiffness of the sensing membrane structure (e.g., sensing membrane structure 110) in response to the external input based on one or more of a lateral thickness of the pillar structure (e.g., pillar structure 122), an area of the spring membrane (e.g., spring membrane 126), or a thickness of the spring membrane, for example, as further described herein regarding FIGS. 1 and 3-4.

In addition, disclosed embodiments of an exemplary MEMS apparatus (e.g., MEMS device or sensor 100/2400) can further comprise one or more electrode (e.g., electrode 116, facing electrode 2404) associated with the backplate structure (e.g., backplate structure 114) and configured to sense deformation of the sensing membrane structure (e.g., sensing membrane structure 110). In further non-limiting embodiments, an exemplary MEMS apparatus (e.g., MEMS device or sensor 100/2400) can further comprise a set of electrode structures associated with the one or more electrode (e.g., electrode 116, facing electrode 2404) that positions the one or more electrode (e.g., electrode 116, facing electrode 2404) in proximity to the sensing membrane structure (e.g., sensing membrane structure 110). In still further non-limiting embodiments, an exemplary MEMS apparatus (e.g., MEMS device or sensor 100/2400) can further comprise a set of electrical contacts (e.g., one or more of substrate contact pad 140, sensing membrane structure 110 contact pad 142, and/or backplate structure 114 contact pad 144) that can be electrically coupled with respective portions of the sensing membrane structure (e.g., sensing membrane structure 110), the backplate structure (e.g., backplate structure 114), or combinations thereof.

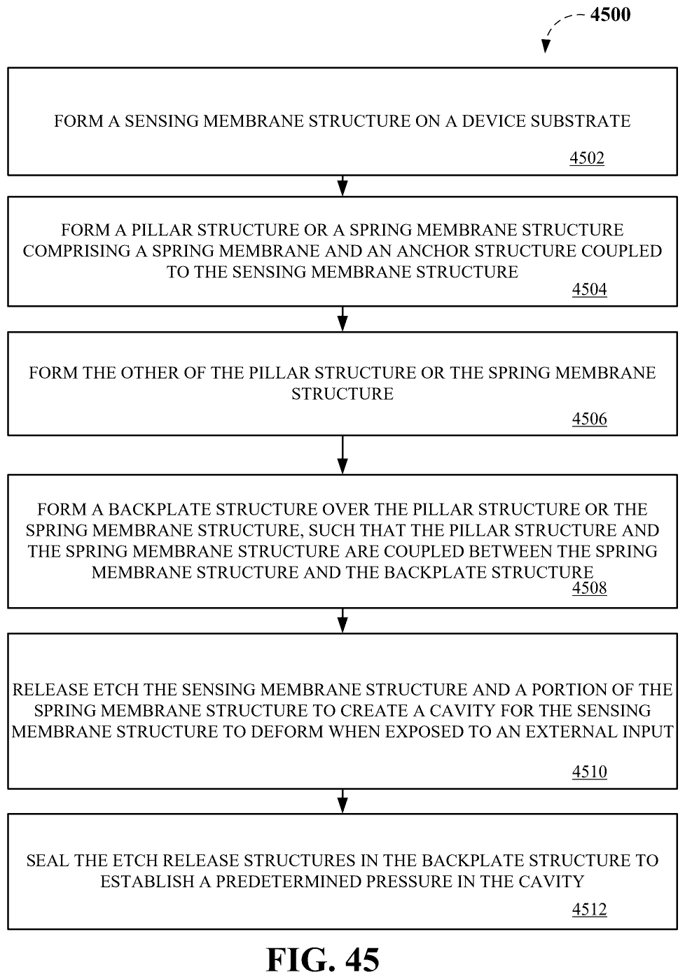

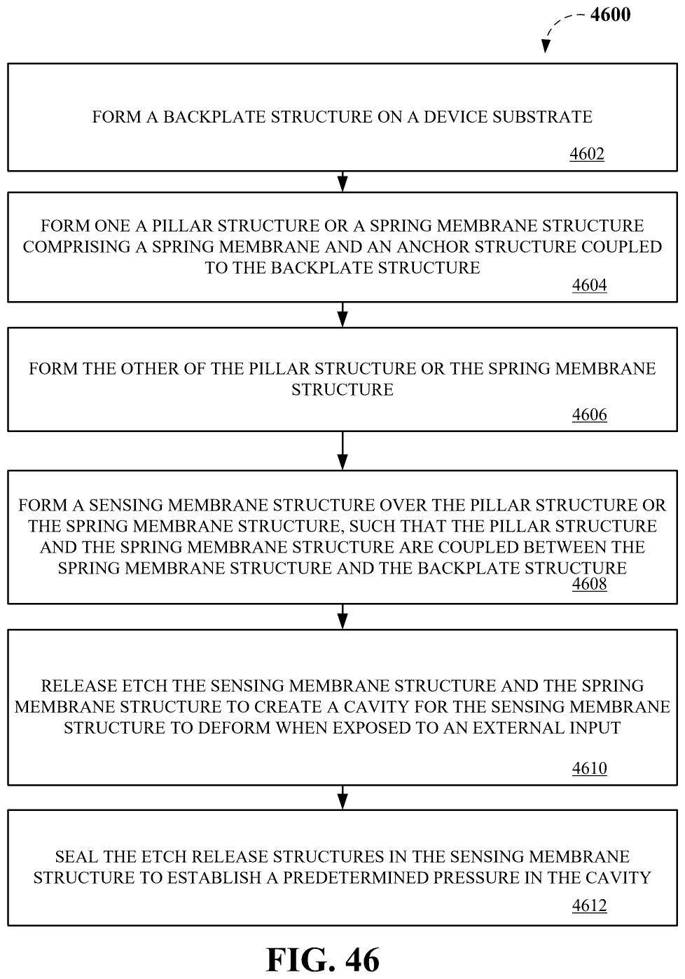

In view of the subject matter described supra, methods that can be implemented in accordance with the subject disclosure will be better appreciated with reference to the flowcharts of FIGS. 45-46. While for purposes of simplicity of explanation, the methods are shown and described as a series of blocks, it is to be understood and appreciated that such illustrations or corresponding descriptions are not limited by the order of the blocks, as some blocks may occur in different orders and/or concurrently with other blocks from what is depicted and described herein. Any non-sequential, or branched, flow illustrated via a flowchart should be understood to indicate that various other branches, flow paths, and orders of the blocks, can be implemented which achieve the same or a similar result. Moreover, not all illustrated blocks may be required to implement the methods described hereinafter.

### EXEMPLARY METHODS

FIG. 45 provides a non-limiting flow diagram of exemplary methods 4500 according to various non-limiting aspects as described herein, for example, as further described herein regarding FIGS. 1 and 5-23. For instance, at 4502, exemplary methods 4500 of fabricating MEMS sensors or devices 100 can comprise forming a sensing membrane structure (e.g., sensing membrane structure 110) on a device substrate 102 (e.g., a wafer substrate, a silicon 104 wafer), as further described herein, for example, regarding FIGS. 1 and 5-23. In a non-limiting aspect, forming the sensing membrane structure (e.g., sensing membrane structure 110) can comprise forming the sensing membrane structure (e.g., sensing membrane structure 110) of a capacitive or a piezoelectric microelectromechanical systems (MEMS) sensor in one or more of a circular shape, a donut shape, or a rectangular shape. Exemplary methods 4500 can further comprise, at 4504, forming one or more of a pillar structure (e.g., pillar structure 122) or a spring membrane structure (e.g., spring membrane structure 124) comprising a spring membrane and an anchor structure (e.g., anchor structure 128) coupled to the sensing membrane structure (e.g., sensing membrane structure 110).

In a further non-limiting aspect, exemplary methods 4500 can further comprise, at 4506, forming an other of the one or more of the pillar structure (e.g., pillar structure 122) or the spring membrane structure (e.g., spring membrane structure 124) comprising the spring membrane (e.g., spring membrane 126) and the anchor structure (e.g., anchor structure 128) over the sensing membrane structure (e.g., sensing membrane structure 110), for example, as further described herein regarding FIGS. 1 and 5-23. In addition, exemplary methods 4500 can further comprise, forming one or more electrode (e.g., electrode 116, facing electrode 2404) associated with the backplate structure (e.g., backplate structure 114), wherein the one or more electrode (e.g., electrode 116, facing electrode 2404) is configured to sense deformation of the sensing membrane structure (e.g., sensing membrane structure 110).

In still further non-limiting embodiments, exemplary methods 4500 can comprise, at 4508, forming a backplate structure (e.g., backplate structure 114) over the other of the one or more of the pillar structure (e.g., pillar structure 122) or the spring membrane structure (e.g., spring membrane structure 124), such that the pillar structure (e.g., pillar structure 122) and the spring membrane structure (e.g., spring membrane structure 124) are coupled between the spring membrane structure (e.g., spring membrane structure 124) and the backplate structure (e.g., backplate structure 114), as further described herein, for example, regarding FIGS. 1 and 5-23.

In other non-limiting embodiments, exemplary methods 4500 can comprise, at 4510, release etching, via a set of etch release structures in the backplate structure (e.g., backplate structure 114), the sensing membrane structure (e.g., sensing membrane structure 110) and at least a portion of the spring membrane structure (e.g., spring membrane structure 124) to create a cavity for the sensing membrane structure (e.g., sensing membrane structure 110) to deform when exposed to an external input, as further described herein, for example, regarding FIGS. 1 and 5-23. In further non-limiting embodiments, exemplary methods 4500 can comprise, at 4512, sealing the set of etch release structures in the backplate structure (e.g., backplate structure 114) to establish a predetermined pressure in the cavity, as further described herein, for example, regarding FIGS. 1 and 5-23. In still further non-limiting embodiments, exemplary methods 4500 can comprise any one or more of the various process steps described in detail regarding FIGS. 6-23.

FIG. 46 provides a non-limiting flow diagram of exemplary methods 4600 according to various non-limiting aspects as described herein, for example, as further described herein regarding FIGS. 24-44. For instance, at 4602, exemplary methods 4600 of fabricating MEMS sensors or devices 100 can comprise forming a backplate structure (e.g., backplate structure 114) on a device substrate 102 (e.g., a wafer substrate, a silicon 104 wafer), as further described herein, for example, regarding FIGS. 24-44. Exemplary methods 4600 can further comprise, at 4604, forming one or more of a pillar structure (e.g., pillar structure 122) or a spring membrane structure (e.g., spring membrane structure 124) comprising a spring membrane (e.g., spring membrane 126) and an anchor structure (e.g., anchor structure 128) coupled to the backplate structure (e.g., backplate structure 114).

In further non-limiting embodiments, exemplary methods 4600 can comprise, at 4606, forming an other of the one or more of the pillar structure (e.g., pillar structure 122) or the spring membrane structure (e.g., spring membrane structure 124) comprising the spring membrane (e.g., spring membrane 126) and the anchor structure (e.g., anchor structure 128) over the backplate structure (e.g., backplate structure 114), for example, as further described herein regarding FIGS. 24-44.

In still further non-limiting embodiments, exemplary methods 4600 can comprise, at 4608, forming a sensing membrane structure (e.g., sensing membrane structure 110) over the other of the one or more of the pillar structure (e.g., pillar structure 122) or the spring membrane structure (e.g., spring membrane structure 124), such that the pillar structure (e.g., pillar structure 122) and the spring membrane structure (e.g., spring membrane structure 124) are coupled between the spring membrane structure (e.g., spring membrane structure 124) and the backplate structure (e.g., backplate structure 114), for example, as further described herein regarding FIGS. 24-44. In a non-limiting aspect, forming the sensing membrane structure (e.g., sensing membrane structure 110) can comprise forming the sensing membrane structure (e.g., sensing membrane structure 110) of a capacitive or a piezoelectric microelectromechanical systems (MEMS) sensor in one or more of a circular shape, a donut shape, or a rectangular shape.

In other non-limiting embodiments, exemplary methods 4600 can comprise, at 4610, release etching, via a set of etch release structures in the sensing membrane structure (e.g., sensing membrane structure 110), the sensing membrane structure (e.g., sensing membrane structure 110) and at least a portion of the spring membrane structure (e.g., spring membrane structure 124) to create a cavity for the sensing membrane structure (e.g., sensing membrane structure 110) to deform when exposed to an external input, for example, as further described herein regarding FIGS. 24-44. In further non-limiting embodiments, exemplary methods 4600 can comprise, at 4612, sealing the set of etch release structures in the sensing membrane structure (e.g., sensing membrane 110) to establish a predetermined pressure in the cavity, as further described herein, for example, regarding FIGS. 24-44. In still further non-limiting embodiments, exemplary methods 4600 can comprise any one or more of the various process steps described in detail regarding FIGS. 24-44.

What has been described above includes examples of the embodiments of the subject disclosure. It is, of course, not possible to describe every conceivable combination of configurations, components, and/or methods for purposes of describing the claimed subject matter, but it is to be appreciated that many further combinations and permutations of the various embodiments are possible. Accordingly, the claimed subject matter is intended to embrace all such alterations, modifications, and variations that fall within the spirit and scope of the appended claims. While specific embodiments and examples are described in subject disclosure illustrative purposes, various modifications are possible that are considered within the scope of such embodiments and examples, as those skilled in the relevant art can recognize. For example, while embodiments of the subject disclosure are described herein in the context of MEMS sensors (e.g., such as MEMS acoustic sensors), it can be appreciated that the subject disclosure is not so limited. For instance, various exemplary implementations may find application in other areas of MEMS sensors, devices, and methods, without departing from the subject matter described herein.

In addition, the words “example” or “exemplary” is used herein to mean serving as an example, instance, or illustration. Any aspect or design described herein as “exemplary” is not necessarily to be construed as preferred or advantageous over other aspects or designs. Rather, use of the word, “exemplary,” is intended to present concepts in a concrete fashion. As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form.

In addition, while an aspect may have been disclosed with respect to only one of several embodiments, such feature may be combined with one or more other features of the other embodiments as may be desired and advantageous for any given or particular application. Furthermore, to the extent that the terms “includes,” “including,” “has,” “contains,” variants thereof, and other similar words are used in either the detailed description or the claims, these terms are intended to be inclusive in a manner similar to the term “comprising” as an open transition word without precluding any additional or other elements.

What is claimed is:

1. A microelectromechanical systems (MEMS) apparatus comprising:
a sensing membrane structure that is configured to deform when exposed to an external input;
a backplate structure;
a pillar structure coupled to one of the sensing membrane structure or the backplate structure; and
a spring membrane structure comprising a spring membrane and an anchor structure, wherein the pillar structure is coupled between the one of the sensing membrane structure or the backplate structure and the spring membrane, and wherein the anchor structure is coupled between the spring membrane and an other one of the sensing membrane structure or the backplate structure.

2. The MEMS apparatus of claim 1, wherein the spring membrane structure and the pillar structure provide a predetermined level of stiffness of the sensing membrane structure in response to the external input based at least in part on at least one of a lateral thickness of the pillar structure, an area of the spring membrane, or a thickness of the spring membrane.

3. The MEMS apparatus of claim 1, wherein the pillar structure is coupled between the sensing membrane structure and the spring membrane structure and wherein the anchor structure is coupled between the spring membrane and the backplate structure.

4. The MEMS apparatus of claim 1, wherein the MEMS apparatus comprises a capacitive MEMS sensor.

5. The MEMS apparatus of claim 4, wherein the capacitive MEMS sensor comprises at least one of a capacitive MEMS acoustic sensor, a capacitive MEMS ultrasonic sensor, or a capacitive MEMS pressure sensor.

6. The MEMS apparatus of claim 1, further comprising:
a sealed cavity located between the sensing membrane structure and the backplate structure.

7. The MEMS apparatus of claim 1, further comprising:
at least one electrode associated with the backplate structure and configured to sense deformation of the sensing membrane structure.

8. The MEMS apparatus of claim 7, further comprising:
a set of electrode structures associated with the at least one electrode that positions the at least one electrode in proximity to the sensing membrane structure.

9. The MEMS apparatus of claim 1, further comprising:
a set of electrical contacts that are electrically coupled with respective portions of at least the sensing membrane structure and the backplate structure.

10. The MEMS apparatus of claim 1, wherein the external input comprises at least one of an acoustic pressure, an ultrasonic pressure, or an environmental pressure.

11. The MEMS apparatus of claim 1, wherein the sensing membrane structure comprises at least one of a circular shape, a donut shape, or a rectangular shape, and wherein the spring membrane structure comprises a shape corresponding to the sensing membrane structure.

12. The MEMS apparatus of claim 1, wherein the sensing membrane structure comprises a piezoelectric material, and wherein the MEMS apparatus comprises at least one of a piezoelectric MEMS acoustic sensor, a piezoelectric MEMS ultrasonic sensor, or a piezoelectric MEMS pressure sensor.

13. A method comprising:
forming a backplate structure on a device substrate;
forming at least one of a pillar structure or a spring membrane structure comprising a spring membrane and an anchor structure coupled to the backplate structure;
forming an other of the at least one of the pillar structure or the spring membrane structure comprising the spring membrane and the anchor structure over the backplate structure; and
forming a sensing membrane structure over the other of the at least one of the pillar structure or the spring membrane structure, such that the pillar structure and the spring membrane structure are coupled between the spring membrane structure and the backplate structure.

14. The method of claim 13, further comprising:
release etching, via a plurality of etch release structures in the sensing membrane structure, the sensing membrane structure and at least a portion of the spring membrane structure to create a cavity for the sensing membrane structure to deform when exposed to an external input.

15. The method of claim 13, further comprising:
forming at least one electrode in the cavity and associated with the backplate structure, wherein the at least one electrode is configured to sense deformation of the sensing membrane structure.

16. The method of claim 13, wherein the forming the sensing membrane structure comprises forming the sensing membrane structure of at least one of a capacitive or a piezoelectric microelectromechanical systems (MEMS) sensor in at least one of a circular shape, a donut shape, or a rectangular shape.

17. A method comprising:
forming a sensing membrane structure on a device substrate;
forming at least one of a pillar structure or a spring membrane structure comprising a spring membrane and an anchor structure coupled to the sensing membrane structure;
forming an other of the at least one of the pillar structure or the spring membrane structure comprising the spring membrane and the anchor structure over the sensing membrane structure; and
forming a backplate structure over the other of the at least one of the pillar structure or the spring membrane structure, such that the pillar structure and the spring membrane structure are coupled between the spring membrane structure and the backplate structure.

18. The method of claim 17, further comprising:
release etching, via a plurality of etch release structures in the backplate structure, the sensing membrane structure and at least a portion of the spring membrane structure to create a cavity for the sensing membrane structure to deform when exposed to an external input; and
sealing the plurality of etch release structures in the backplate structure to establish a predetermined pressure in the cavity.

19. The method of claim 18, further comprising:
forming a port in the device substrate to expose the sensing membrane structure to the external input.

20. The method of claim 17, further comprising:
forming at least one electrode associated with the backplate structure, wherein the at least one electrode is configured to sense deformation of the sensing membrane structure.

21. The method of claim 17, wherein the forming the sensing membrane structure comprises forming the sensing membrane structure of at least one of a capacitive or a piezoelectric microelectromechanical systems (MEMS) sensor in at least one of a circular shape, a donut shape, or a rectangular shape.
